(19) United States
(12) Patent Application Publication
(10) Pub. No.: US 2026/0181951 A1
(43) Pub. Date: Jun. 25, 2026

(54) STACKED DEVICE HAVING STACKED DIELECTRIC STRUCTURES WITH DIFFERENT STRESSES AND MANUFACTURING METHOD THEREOF

(71) Applicant: TAIWAN SEMICONDUCTOR MANUFACTURING COMPANY, LTD., Hsinchu (TW)

(72) Inventors: Zhi-Chang LIN, Hsinchu County (TW); Szu-Hua CHEN, Tainan City (TW); Yung-Ta CHEN, Taichung City (TW); Chia-Jung TSAI, Hsinchu City (TW)

(73) Assignee: TAIWAN SEMICONDUCTOR MANUFACTURING COMPANY, LTD., Hsinchu (TW)

(21) Appl. No.: 19/000,042

(22) Filed: Dec. 23, 2024

(51) Int. Cl. H10D 30/67; H10D 30/00; H10D 30/01; H10D 62/10; H10D 62/13; H10D 64/01; H10D 64/23; H10D 84/85

(52) U.S. Cl. CPC H10D 30/6735; H10D 30/0191; H10D 30/502; H10D 30/6757; H10D 62/115; H10D 62/121; H10D 62/151; H10D 64/017; H10D 64/251; H10D 84/851

(57) ABSTRACT

A device includes a first bottom transistor, a second bottom transistor, a first top transistor, a second top transistor, a bottom dielectric structure, and a top dielectric structure. The first top transistor is over the first bottom transistor. The second top transistor is over the second bottom transistor. The bottom dielectric structure is between the first bottom transistor and the second bottom transistor. The top dielectric structure is between the first top transistor and the second top transistor and in contact with the bottom dielectric structure. The bottom dielectric structure and the top dielectric structure have different stresses.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an integrated circuit structure (or a semiconductor device) in accordance with some embodiments of the present disclosure.

FIGS. 2-11C illustrate perspective views and cross-sectional views of intermediate stages in the formation of an integrated circuit structure (or a semiconductor device) in accordance with some embodiments of the present disclosure.

FIGS. 12A and 12B are cross-sectional view of integrated circuit structure (or a semiconductor device) in accordance with some embodiments of the present disclosure.

FIGS. 13A and 13B are cross-sectional view of integrated circuit structure (or a semiconductor device) in accordance with some embodiments of the present disclosure.

FIGS. 14A-15B illustrate exemplary cross-sectional views of various stages for manufacturing an integrated circuit structure (or a semiconductor device) according to some other embodiments of the present disclosure.

FIGS. 16A-18B illustrate exemplary cross-sectional views of various stages for manufacturing an integrated circuit structure (or a semiconductor device) according to some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

As used herein, the term “etch selectivity” refers to the ratio of the etch rates of two different materials under the same etching conditions. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9). As used herein, the term “low-k” refers to a low dielectric constant. In the field of semiconductor device structures and manufacturing processes, low-k refers to a dielectric constant that is less than the dielectric constant of SiO₂ (e.g., less than 3.9). As used herein, the term “p-type” defines a structure, layer, and/or region as being doped with p-type dopants, such as boron. As used herein, the term “n-type” defines a structure, layer, and/or region as being doped with n-type dopants, such as phosphorus. As used herein, the term “conductive” refers to an electrically conductive structure, layer, and/or region. As used herein, source/drain region(s) may refer to a source or a drain, individually or collectively dependent upon the context.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit structures and methods of forming the same. More particularly, some embodiments of the present disclosure are related to stacked GAA devices including stacked dielectric structures for isolating neighboring gate structures. The stacked dielectric structures have different stresses to restore channel stresses for different GAA devices.

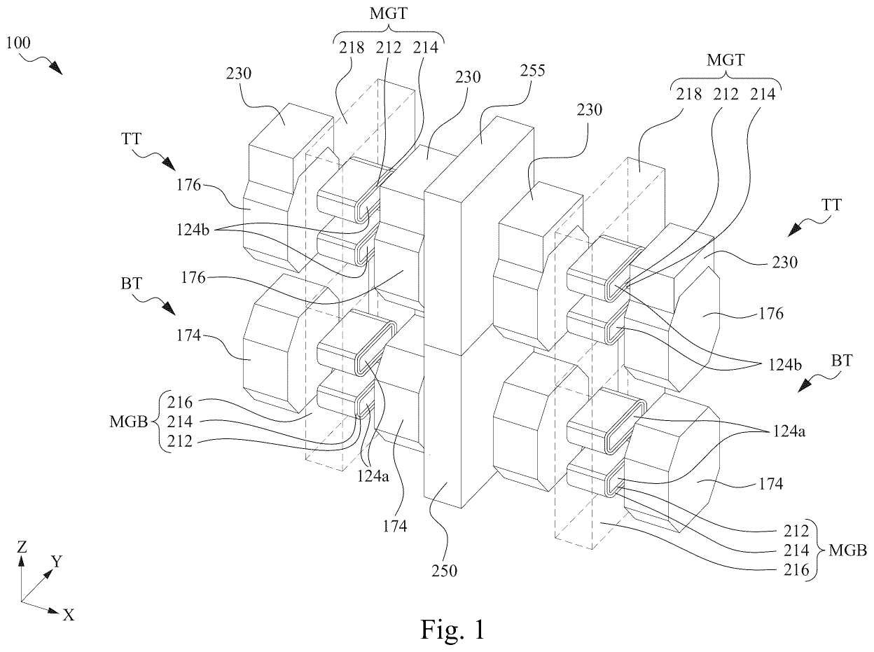

FIG. 1 is a perspective view of an integrated circuit structure (or a semiconductor device) 100 in accordance with some embodiments of the present disclosure. In the present disclosure, a semiconductor device 100 is provided, and its manufacturing method will be disclosed in the following discussion. In addition to the semiconductor device 100, FIG. 1 depicts X-axis, Y-axis, and Z-axis directions. In the semiconductor device 100, top transistors TT are disposed vertically above respective bottom transistors BT. In some embodiments, the bottom transistors BT and the top transistors TT each may be field effect transistor (FET) and may both include gate-all-around (GAA) configuration, and thus the bottom transistors BT and the top transistors TT can also be referred to as GAA FETs. Each of the bottom transistors BT includes epitaxial layers 124a vertically stacked one above another, a gate structure MGB wrapping around each of the epitaxial layers 124a, and first source/drain epitaxial structures 174 on opposite ends of each of the epitaxial layers 124a. Similarly, each of the top transistors TT includes epitaxial layers 124b vertically stacked one above another, a gate structure MGT wrapping around each of the epitaxial layers 124b, and second source/drain epitaxial structures 176 on opposite ends of each of the epitaxial layers 124b.

Each of the gate structure MGB may include interfacial layers 212, high-k gate dielectric layers 214, and a work function metal layer 216. Similarly, each of the gate structure MGT may include the interfacial layers 212, the high-k gate dielectric layers 214, and a work function metal layer 218. In some embodiments, each of the bottom transistors BT has a first conductivity type (e.g., p-type) and each of the top transistors TT has a second conductivity type (e.g., n-type) different from the first conductivity type. In some embodiments, the bottom transistors BT can be referred to as P-FETs, and the top transistors TT can be referred to as N-FETs. The semiconductor device 100 further includes source/drain contacts 230 disposed over the respective second source/drain epitaxial structures 176. In some embodiments, the source/drain contacts 230 are respectively in contact with top surfaces of the corresponding second source/drain epitaxial structures 176.

A bottom dielectric structure 250 is disposed between two adjacent bottom transistors BT, and a top dielectric structure 255 is disposed between two adjacent top transistors TT. The stacked dielectric structures (i.e., the bottom dielectric structure 250 and the top dielectric structure 255) have different stresses. For example, the bottom dielectric structure 250 has a tensile stress, which stresses the epitaxial layers 124a so as to restore the stress of the epitaxial layers 124a. Therefore, the epitaxial layers 124a have sufficient compressive stress for the p-type bottom transistors BT. Likewise, the top dielectric structure 255 has a compressive stress, which strains the epitaxial layers 124b so as to restore the stress of the epitaxial layers 124b. Therefore, the epitaxial layers 124b have sufficient tensile stress for the n-type top transistors TT.

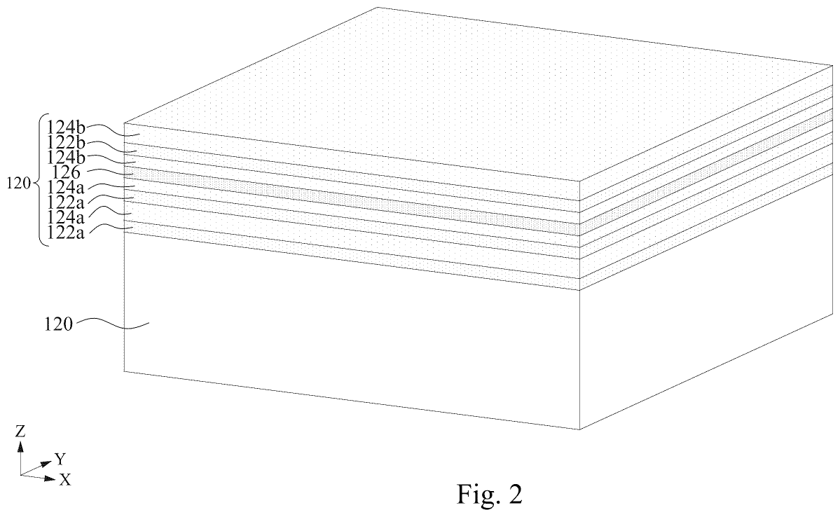

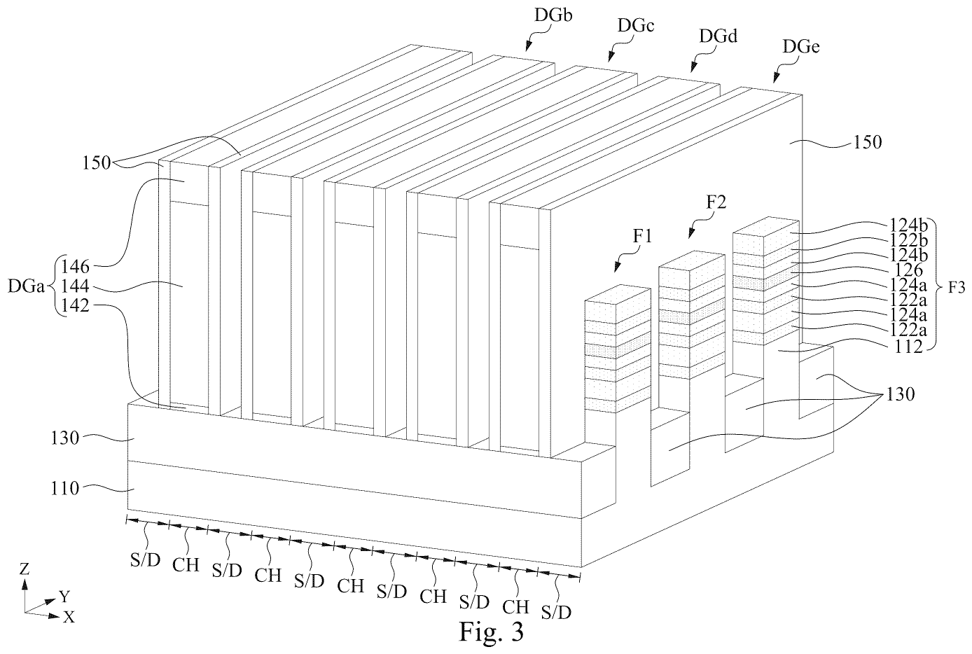

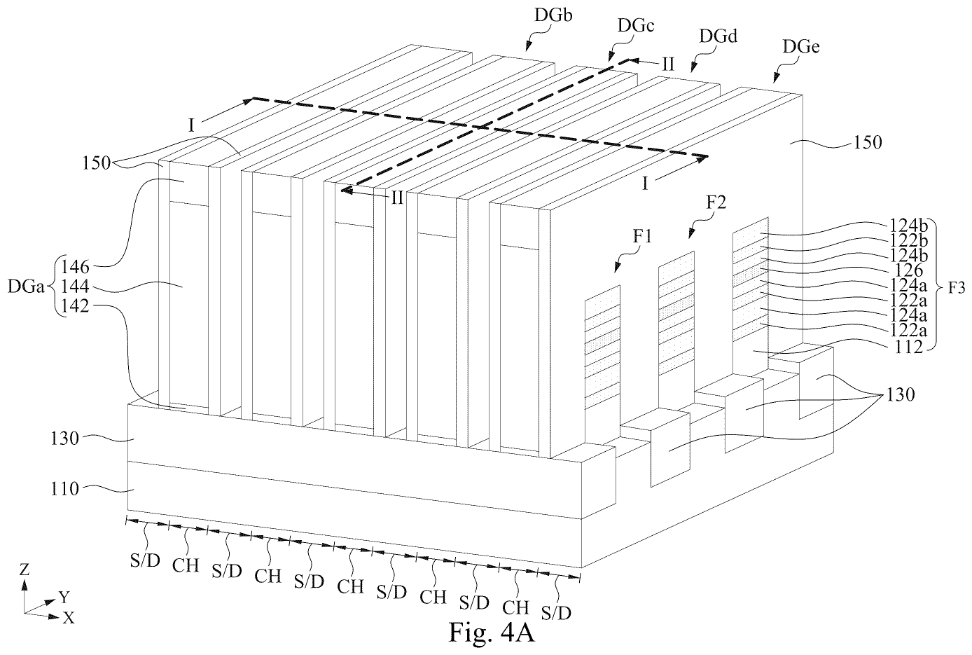

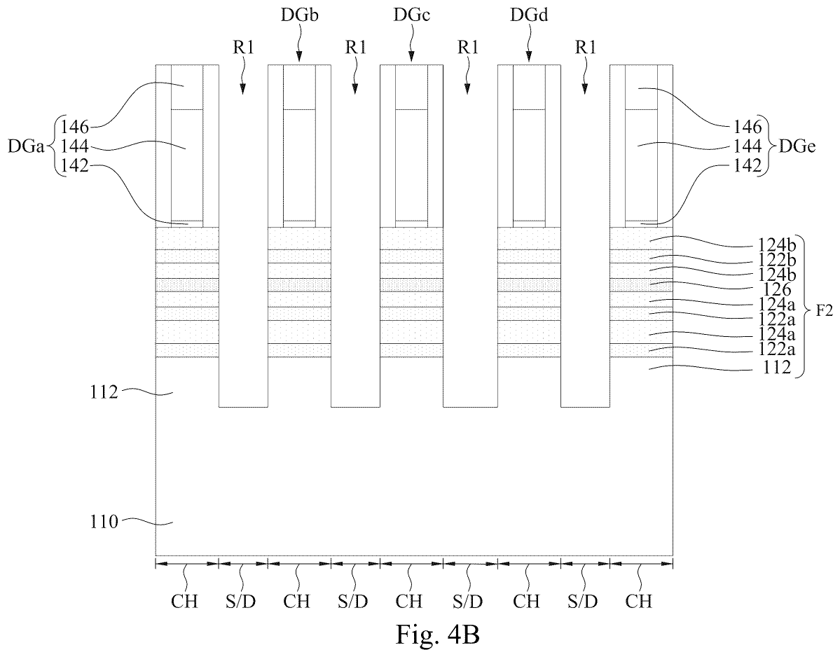

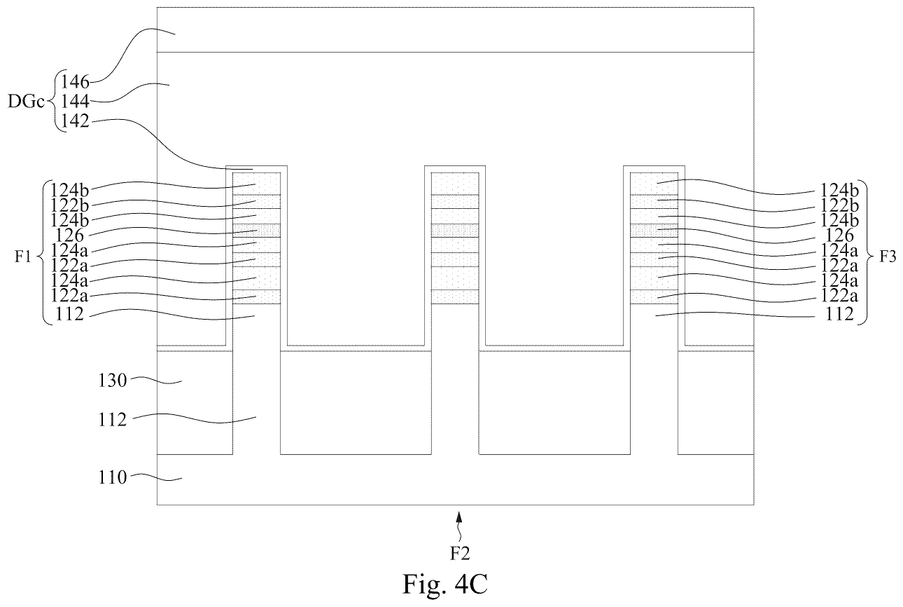

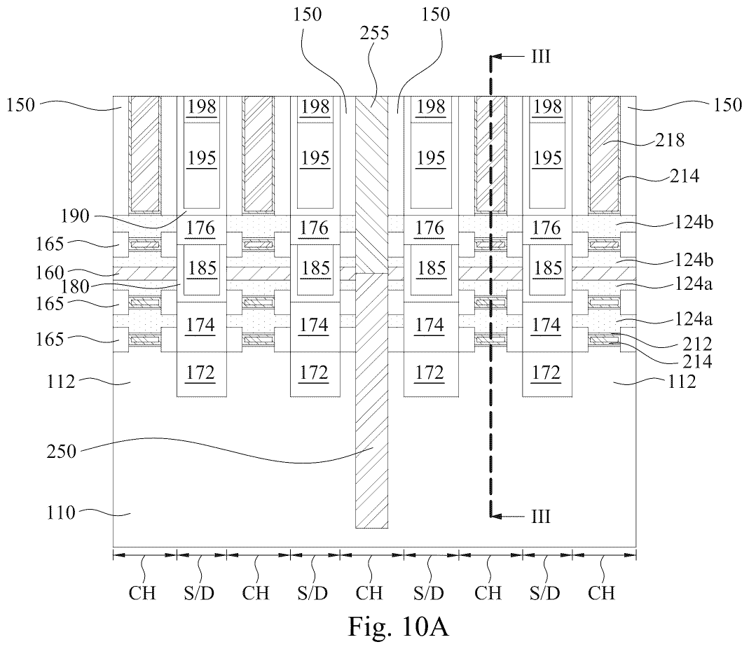

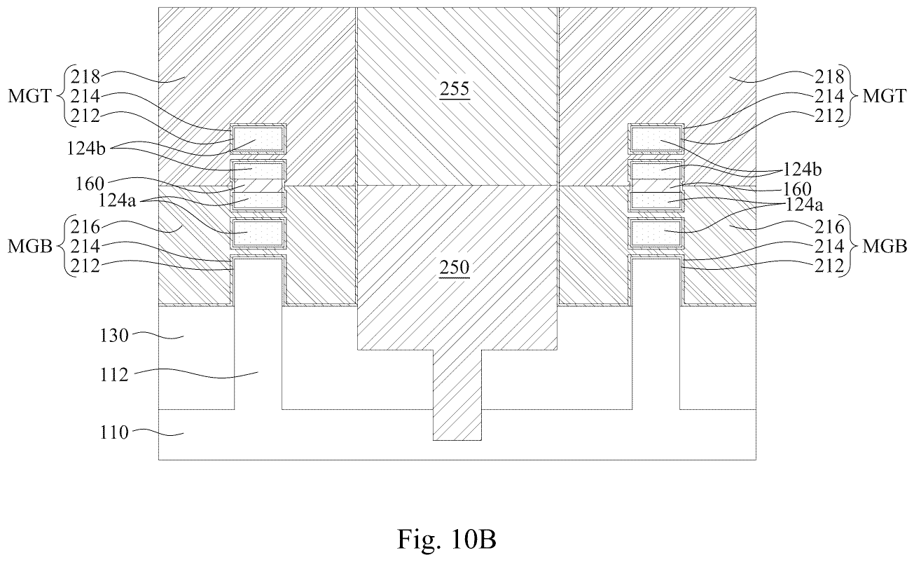

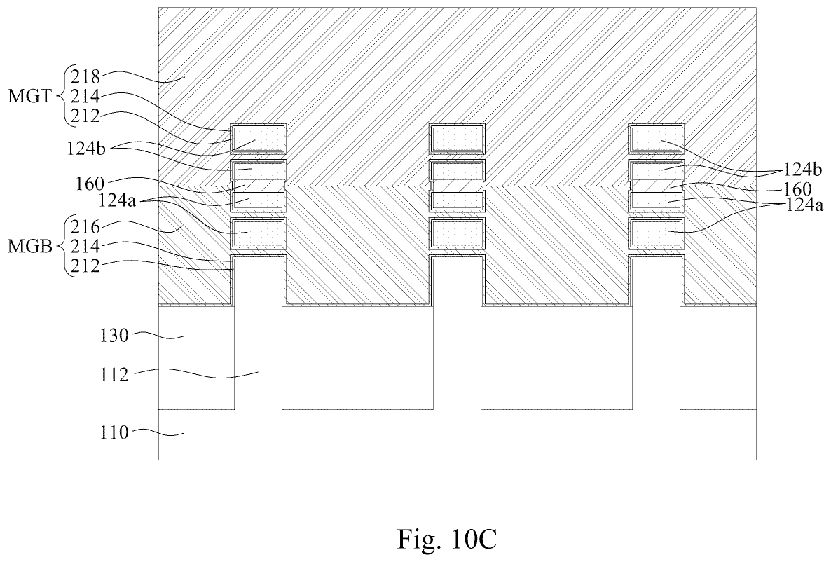

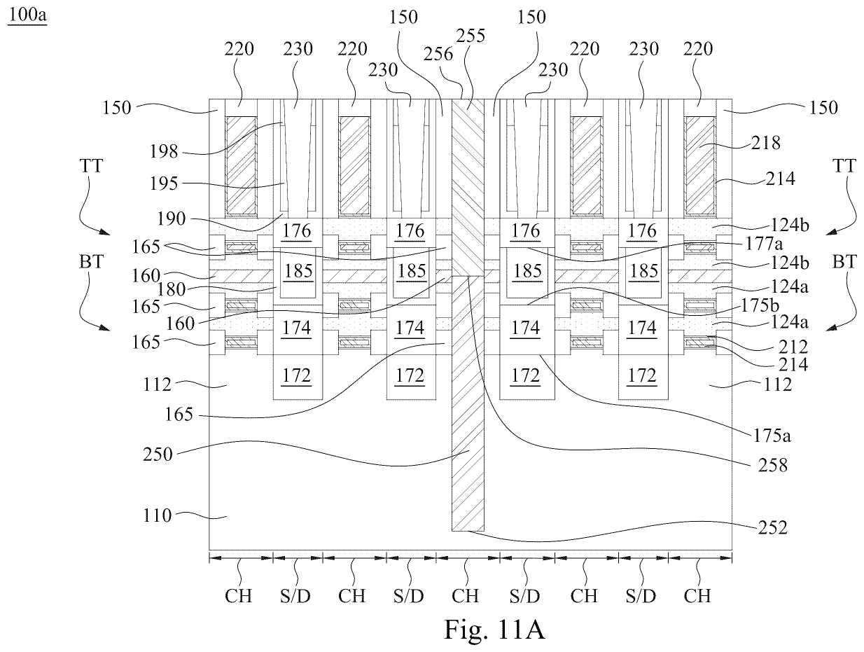

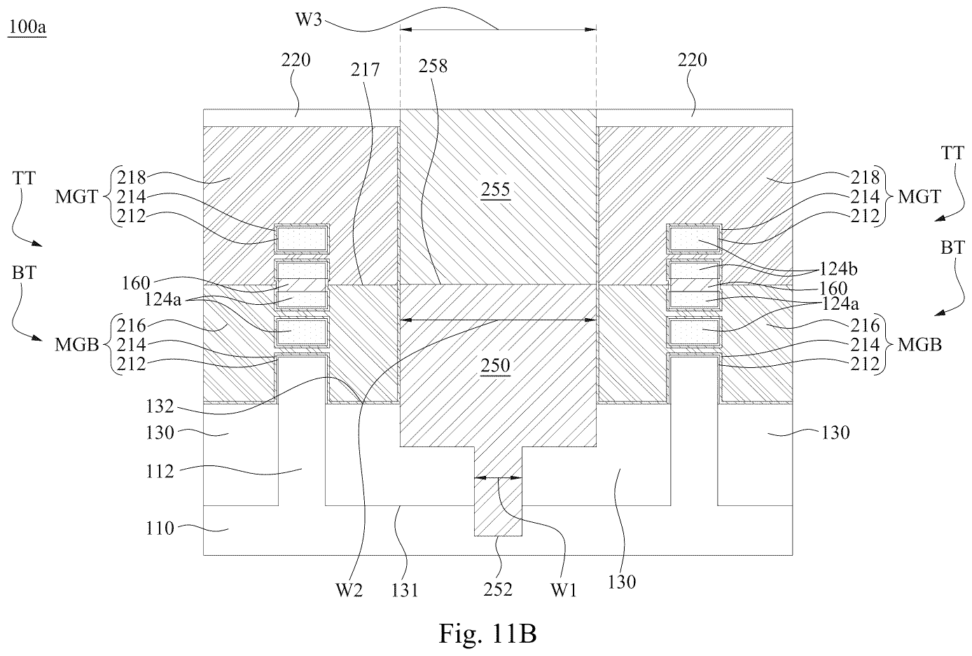

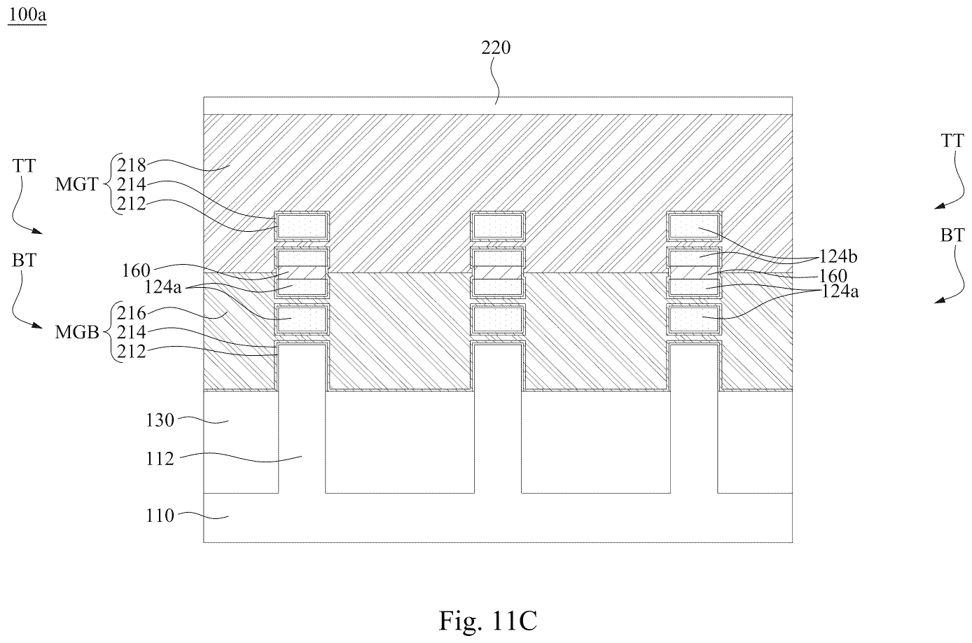

FIGS. 2-11C illustrate perspective views and cross-sectional views of intermediate stages in the formation of an integrated circuit structure (or a semiconductor device) 100a in accordance with some embodiments of the present disclosure. In some embodiments, the semiconductor device 100a in FIGS. 11A-11C is a complementary FET (CFET) device. In addition to the semiconductor device 100a, FIGS. 2-4A depict X-axis, Y-axis, and Z-axis directions. FIGS. 4B, 5A, 6A, 7A, 8A, 9A, 10A, and 11A are cross-sectional views of some embodiments of the semiconductor device 100a at intermediate stages along a first cut (e.g., cut I-I in FIG. 4A). FIGS. 4C, 5B, 6B, 7B, 8B, 9B, 10B, and 11B are cross-sectional views of some embodiments of the semiconductor device 100a at intermediate stages along a second cut (e.g., cut II-II in FIG. 4A). FIGS. 10C and 11C are cross-sectional views of some embodiments of the semiconductor device 100a at intermediate stages along a third cut (e.g., cut III-III in FIG. 10A). The formed devices include p-type transistors (such as p-type GAA FETs) and n-type transistors (such as an n-type GAA FETs) in accordance with some exemplary embodiments. Throughout the various views and illustrative embodiments, like reference numbers are used to designate like elements. It is understood that additional operations can be provided before, during, and after the processes shown by FIGS. 2-11C, and some of the operations described below can be replaced or eliminated, for additional embodiments of the method. The order of the operations/processes may be interchangeable.

Referring to FIG. 2, an epitaxial stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or combinations thereof) or other appropriate semiconductor materials. In some embodiments, the substrate 110 may include a semiconductor-on-insulator (SOI) structure such as a buried dielectric layer. Also alternatively, the substrate 110 may include a buried dielectric layer such as a buried oxide (BOX) layer, such as that formed by a method referred to as separation by implantation of oxygen (SIMOX) technology, wafer bonding, SEG, or another appropriate method.

The epitaxial stack 120 includes epitaxial layers 122a and 122b of a first composition interposed by epitaxial layers 124a and 124b of a second composition arranged in a stacking direction (Z-axis in this case). The epitaxial stack 120 further includes an epitaxial layer 126 between the topmost epitaxial layer 124a and the bottommost epitaxial layer 124b of a third composition. The first, second, and third compositions are different. In some embodiments, the epitaxial layers 122a, 122b, and 126 are SiGe and the epitaxial layers 124a and 124b are silicon (Si). Further, the germanium concentration of the epitaxial layer 126 is higher than the germanium concentration of the epitaxial layer 122a and 122b. However, other embodiments are possible including those that provide for a first composition, a second composition, and a third composition having different etch selectivity.

The epitaxial layers 124a and 124b or portions thereof may form nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The use of the epitaxial layers 124a and 124b to define a channel or channels of a device is further discussed below.

In FIG. 2, the epitaxial layers 124b are disposed above the epitaxial layers 124a. It is noted that two layers of the epitaxial layers 124a and two layers of the epitaxial layers 124b are arranged as illustrated in FIG. 2, which is for illustrative purposes only and not intended to be limiting beyond what is specifically recited in the claims. It can be appreciated that any number of epitaxial layers can be formed in the epitaxial stack 120; the number of layers depending on the desired number of channels regions for the transistor. In some embodiments, the number of each of the epitaxial layers 124a and 124 b is between 2 and 10.

As described in more detail below, the epitaxial layers 124a and 124b may serve as channel region(s) for a subsequently-formed semiconductor device and the thickness is chosen based on device performance considerations. The epitaxial layers 122a and 122b in channel region(s) may eventually be removed and serve to define a vertical distance between adjacent channel region(s) for a subsequently-formed multi-gate device and the thickness is chosen based on device performance considerations. Accordingly, the epitaxial layers 122a and 122b may also be referred to as sacrificial layers, and the epitaxial layers 124a and 124b may also be referred to as channel layers.

By way of example, epitaxial growth of the layers of the epitaxial stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124a and 124b include the same material as the substrate 110. In some embodiments, the epitaxial layers 122a, 122b, 124a, 124b, and 126 include a different material than the substrate 110. As stated above, in at least some examples, the epitaxial layers 122a, 122b, and 126 include an epitaxially grown silicon germanium (SiGe) layer and the epitaxial layers 124a and 124b include an epitaxially grown silicon (Si) layer. Alternatively, in some embodiments, either of the epitaxial layers 122a, 122b, 124a, 124b, and 126 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the epitaxial layers 122a, 122b, 124a, 124b, and 126 may be chosen based on providing differing oxidation and/or etching selectivity properties.

Reference is made to FIG. 3. Fin structures F1, F2, and F3 extending from the substrate 110 are formed. In various embodiments, each of the fin structures F1, F2, and F3 includes a base portion 112 formed from the substrate 110 and portions of each of the epitaxial layers of the epitaxial stack including epitaxial layers 122a, 122b, 124a, 124b, and 126. The fin structures F1, F2, and F3 may be fabricated using suitable processes including double-patterning or multi-patterning processes.

For example, a hard mask (HM) layer is formed over the epitaxial stack 120 prior to forming the fin structures F1, F2, and F3. The fin structures F1, F2, and F3 may subsequently be fabricated using suitable processes including photolithography and etch processes. The photolithography process may include forming a photoresist layer (not shown) over the HM layer, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process using light in EUV region, having a wavelength of, for example, about 1-200 nm. The patterned mask may then be used to protect regions of the substrate 110, and layers formed thereupon, while an etch process forms trenches in unprotected regions through the HM layer, through the epitaxial stack 120, and into the substrate 110, thereby leaving the fin structures F1, F2, and F3. The trenches may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack 120 in the form of the fin structures F1, F2, and F3.

Next, isolation structures 130 are formed to surround the fin structures F1, F2, and F3. The isolation structures 130 may include a liner oxide (not shown). The liner oxide may be formed of a thermal oxide formed through a thermal oxidation of a surface layer of the substrate 110. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The isolation structures 130 may also include a dielectric material over the liner oxide, and the dielectric material may be formed using flowable chemical vapor deposition (FCVD), spin-on coating, or the like.

The isolation structures 130 are then planarized, such that the HM layer is removed, and the top surfaces of the fin structures F1, F2, and F3 are exposed. Subsequently, the isolation structures 130 are recessed, so that the top portions of the fin structures F1, F2, and F3 protrude higher than the top surfaces of the neighboring isolation structures 130. The etching may be performed using a dry etching process, wherein NH₃ and NF₃ are used as the etching gases. In accordance with alternative embodiments of the present disclosure, the recessing of the isolation structures 130 is performed using a wet etch process. The etching chemical may include diluted HF, for example.

Dummy gate structures DGa, DGb, DGc, DGd, and DGe are formed over the substrate 110 and across the fin structures F1, F2, and F3. The portions of the fin structures F1, F2, and F3 underlying the dummy gate structures DGa-DGe may be referred to as the channel regions CH. The dummy gate structures DGa-DGe may also define source/drain regions S/D of the fin structures F1, F2, and F3, for example, the regions of the fin structures F1, F2, and F3 adjacent and on opposite sides of the channel regions CH.

Dummy gate formation operation forms a dummy gate dielectric layer, a dummy gate electrode layer and a hard mask which may include multiple layers (e.g., a nitride layer and an oxide layer) over the dummy gate electrode layer. The hard mask is then patterned, followed by patterning the dummy gate electrode layer by using the patterned hard mask as an etch mask. The etch process may include a wet etch, a dry etch, and/or combinations thereof. As such, dummy gate structures DGa-DGe each including a dummy gate dielectric layer 142, a dummy gate electrode layer 144 and a hard mask layer 146 (e.g., a nitride layer and an oxide layer) are formed.

After formation of the dummy gate structures DGa-DGe is completed, gate spacers 150 are formed on opposite sidewalls of the dummy gate structures DGa-DGe. For example, a spacer material layer is deposited on the substrate 110. The spacer material layer may be a conformal layer that is subsequently etched back to form gate sidewall spacers. In the illustrated embodiments, a spacer material layer is disposed conformally on top and sidewalls of the dummy gate structures DGa-DGe. The spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as a first spacer layer and a second spacer layer formed over the first spacer layer. By way of example, the spacer material layer may be formed by depositing a dielectric material over the dummy gate structures DGa-DGe using suitable deposition processes. An anisotropic etching process is then performed on the deposited spacer material layer to expose portions of the fin structures F1, F2, and F3 not covered by the dummy gate structures DGa-DGe (e.g., over the source/drain regions S/D of the fin structures F1, F2, and F3). Portions of the spacer material layer directly above the dummy gate structures DGa-DGe may be completely removed by this anisotropic etching process. Portions of the spacer material layer on sidewalls of the dummy gate structures DGa-DGe may remain, forming gate sidewall spacers, which are denoted as the gate spacers 150, for the sake of simplicity.

Reference is made to FIGS. 4A, 4B, and 4C, where FIG. 4B is a cross-sectional view taken along line I-I of FIG. 4A, and FIG. 4C is a cross-sectional view taken along line II-II of FIG. 4A. Exposed portions of the fin structures F1, F2, and F3 that extend laterally beyond the gate spacers 150 (e.g., in source/drain regions S/D of the structures F1, F2, and F3) are etched by using, for example, an anisotropic etching process that uses the dummy gate structures DGa-DGe and the gate spacers 150 as an etch mask, resulting in recesses R1 into the fin structures F1, F2, and F3. After the anisotropic etching, end surfaces of the epitaxial layers 122a, 122b, 124a, 124b, 126 and respective outermost sidewalls of the gate spacers 150 are substantially coterminous, due to the anisotropic etching. In some embodiments, the anisotropic etching may be performed by a dry chemical etch with a plasma source and a reaction gas. The plasma source may be an inductively coupled plasma (ICP) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

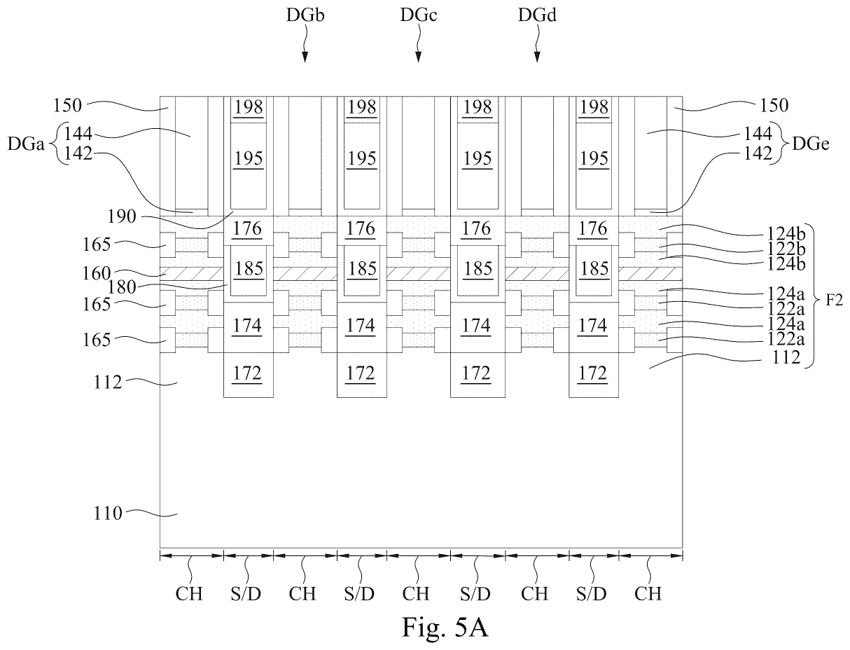

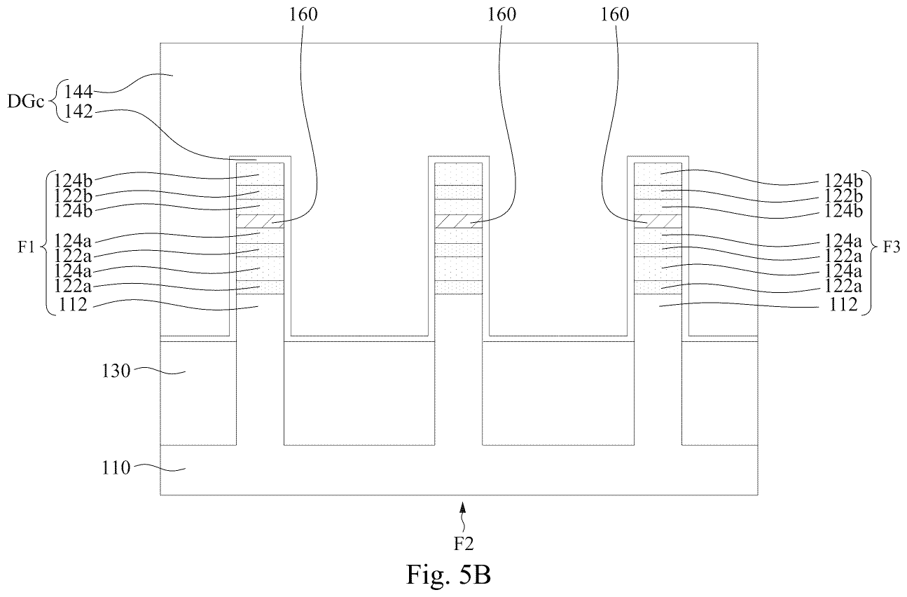

Reference is made to FIGS. 5A and 5B. The epitaxial layers 126 (see FIGS. 4A-4C) are removed, resulting in openings between the topmost epitaxial layers 124a and the bottommost epitaxial layers 124b. Subsequently, middle dielectric isolators 160 are filled in the openings, respectively, such that the middle dielectric isolators 160 are between the epitaxial layers 124a and 124b. For example, a dielectric material layer is formed to fill the opening. The dielectric material layer may be a low-k dielectric material, such as SiO₂, SiN, SiC, SiON, SiCN, or SiOCN, and may be formed by a suitable deposition method, such as ALD. In some embodiments, the dielectric material layer is intrinsic or un-doped with impurities. The dielectric material layer can be formed using CVD, including LPCVD and PECVD, PVD, ALD, or other suitable processes.

After the deposition of the dielectric material layer, an anisotropic etching process may be performed to remove the dielectric material layer outside the openings, such that portions of the deposited dielectric material layer that fill the openings are left. After the etching process, the remaining portions of the deposited spacer material in the openings are denoted as the middle dielectric isolators 160, for the sake of simplicity. The middle dielectric isolator 160 serves to isolate the epitaxial layers 124a from the epitaxial layers 124b.

The epitaxial layers 122a and 122b are then laterally or horizontally recessed by using suitable etch techniques, resulting in lateral recesses each vertically between corresponding epitaxial layers 124a and 124b. These operations may be performed by using selective etching processes. In some embodiments, the selective dry etching etches SiGe at a faster etch rate than it etches Si. In some embodiments, during the selective etching processes, some portions of the epitaxial layers 124a and 124b are also etched as shown in FIG. 5A.

Subsequently, inner dielectric spacers 165 are filled in the recesses, respectively. For example, spacer material layers are formed and then trimmed to fill the recesses. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes.

Next, bottom source/drain epitaxial structures 172, first source/drain epitaxial structures 174, a first contact etch stop layer (CESL) 180, a first interlayer dielectric (ILD) layer 185, second source/drain epitaxial structures 176, a second CESL 190, and a second ILD layer 195 are sequentially formed in the recesses R1 of the fin structures F1, F2, and F3. In some embodiments, semiconductor materials are deposited on the base portions 112 to form the bottom source/drain epitaxial structures 172. The semiconductor materials include a single element semiconductor material, such as germanium (Ge) or silicon (Si), compound semiconductor materials, such as gallium arsenide (GaAs) or aluminum gallium arsenide (AlGaAs), or a semiconductor alloy, such as silicon germanium (SiGe) or gallium arsenide phosphide (GaAsP). The bottom source/drain epitaxial structures 172 have suitable crystallographic orientations (e.g., a (100), (110), or (111) crystallographic orientation). The epitaxial processes include CVD deposition techniques (e.g., vapor-phase epitaxy (VPE) and/or ultra-high vacuum CVD (UHV-CVD)), molecular beam epitaxy, and/or other suitable processes. In some embodiments, the bottom source/drain epitaxial structures 172 are intrinsic. That is, the bottom source/drain epitaxial structures 172 are undoped. The undoped bottom source/drain epitaxial structures 172 are benefit for reducing current leakage from the first source/drain epitaxial structures 174 to the substrate 110. The bottom source/drain epitaxial structures 172 are spaced apart from the bottommost epitaxial layers 124a.

The first source/drain epitaxial structures 174 are on the bottom source/drain epitaxial structures 172, respectively. Specifically, the first source/drain epitaxial structures 174 are on opposite sides and connected to the epitaxial layers 124a and spaced apart from the epitaxial layers 124b. The second source/drain epitaxial structures 176 are on opposite sides and connected to the epitaxial layers 124b and spaced apart from the epitaxial layers 124a. The first source/drain epitaxial structures 174 and the second source/drain epitaxial structures 176 may be formed by performing an epitaxial growth process that provides an epitaxial material on the fin structures F1, F2, and F3. In some embodiments, the lattice constants of the first source/drain epitaxial structures 174 are different from the lattice constant of the epitaxial layers 124a, so that the epitaxial layers 124a can be strained or stressed by the first source/drain epitaxial structures 174 to improve carrier mobility of the semiconductor device and enhance the device performance. Similarly, the lattice constants of the second source/drain epitaxial structures 176 are different from the lattice constant of the epitaxial layers 124b. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the epitaxial layers 124a or 124b.

In some embodiments, the first source/drain epitaxial structures 174 and the second source/drain epitaxial structures 176 may include Ge, Si, GaAs, AlGaAs, SiGe, GaAsP, SiP, or other suitable material. The first source/drain epitaxial structures 174 and the second source/drain epitaxial structures 176 may be in-situ doped during the epitaxial process by introducing doping species including: p-type dopants, such as boron or BF₂; n-type dopants, such as phosphorus or arsenic; and/or other suitable dopants including combinations thereof. If the first source/drain epitaxial structures 174 and/or the second source/drain epitaxial structures 176 are not in-situ doped, an implantation process (i.e., a junction implant process) is performed to dope the first source/drain epitaxial structures 174 and/or second source/drain epitaxial structures 176.

The first CESL 180 is formed on the substrate 110 and covers the bottom source/drain epitaxial structures 172 and the first source/drain epitaxial structures 174. The second CESL 190 covers the second source/drain epitaxial structures 176. In some examples, the first CESL 180 and the second CESL 190 include a silicon nitride layer, silicon oxide layer, a silicon oxynitride layer, and/or other suitable materials. The first CESL 180 and the second CESL 190 may be formed by plasma-enhanced chemical vapor deposition (PECVD) process and/or other suitable deposition or oxidation processes.

The first ILD layer 185 is formed over the first CESL 180, and the second ILD layer 195 is formed over the second CESL 190. In some embodiments, the first ILD layer 185 and the second ILD layer 195 include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the first CESL 180. The first ILD layer 185 and the second ILD layer 195 may be deposited by a PECVD process or other suitable deposition technique.

In some examples, after depositing the second ILD layer 195, a planarization process may be performed to remove excessive materials of the second ILD layer 195. For example, a planarization process includes a chemical mechanical planarization (CMP) process which removes portions of the second ILD layer 195 and the second CESL 190 overlying the dummy gate structures 140 and planarizes a top surface of the semiconductor device 100a. In some embodiments, the CMP process also removes hard mask layers 146 (as shown in FIGS. 4A-4C) and exposes the dummy gate electrode layers 144.

After the CMP process, an etching back process is optionally performed to etch back the second ILD layer 195, resulting in recesses over the etched-back second ILD layer 195. In some embodiments, because the materials of the second ILD layer 195 have a different etch selectivity than the gate spacers 150, the dummy gate electrode layer 144, and the second CESL 190, a selective etching process may be performed to etch back the second ILD layer 195 to lower the second ILD layer 195. As a result, the top surface of the second ILD layer 195 may be at a lower level than the top surfaces of the gate spacers 150 and the second CESL 190.

Subsequently, a dielectric cap layer is deposited over the substrate 110 until the recesses are overfilled. The dielectric cap layer includes SiNₓ, AlₓO_{y}, AlON, SiOₓC_{y}, SiCₓN_{y}, boron nitride (BN), boron carbonitride (BNC), combinations thereof or the like, and is formed by a suitable deposition technique such as CVD, plasma-enhanced CVD (PECVD), ALD, remote plasma ALD (RPALD), plasma-enhanced ALD (PEALD), combinations thereof or the like. A CMP process is then performed to remove the cap layer outside the recess, leaving portions of the dielectric cap layer in the recess to serve as dielectric caps 198. The dielectric caps 198 are in direct contact with the second ILD layer 195 and the second CESL 190 as shown in FIG. 5A.

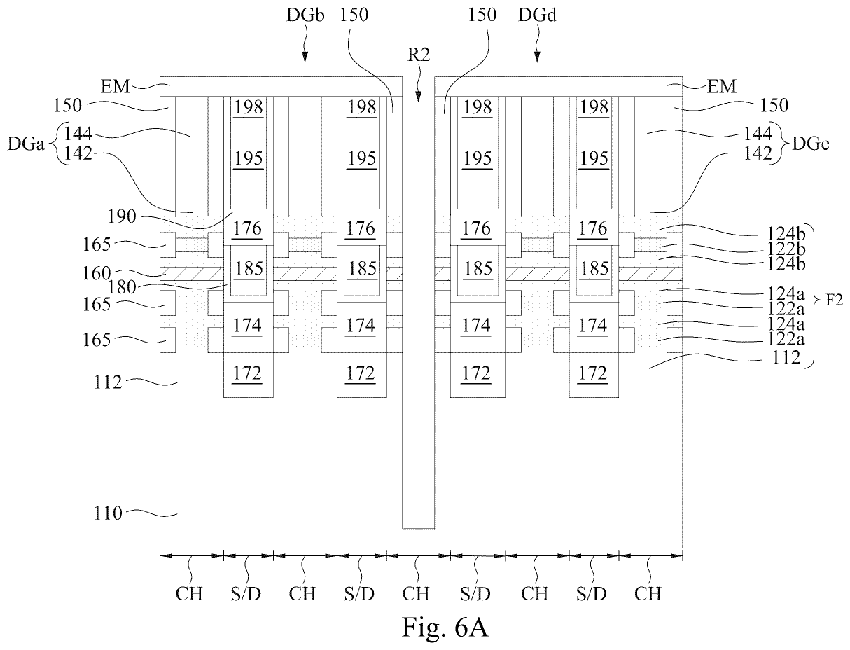

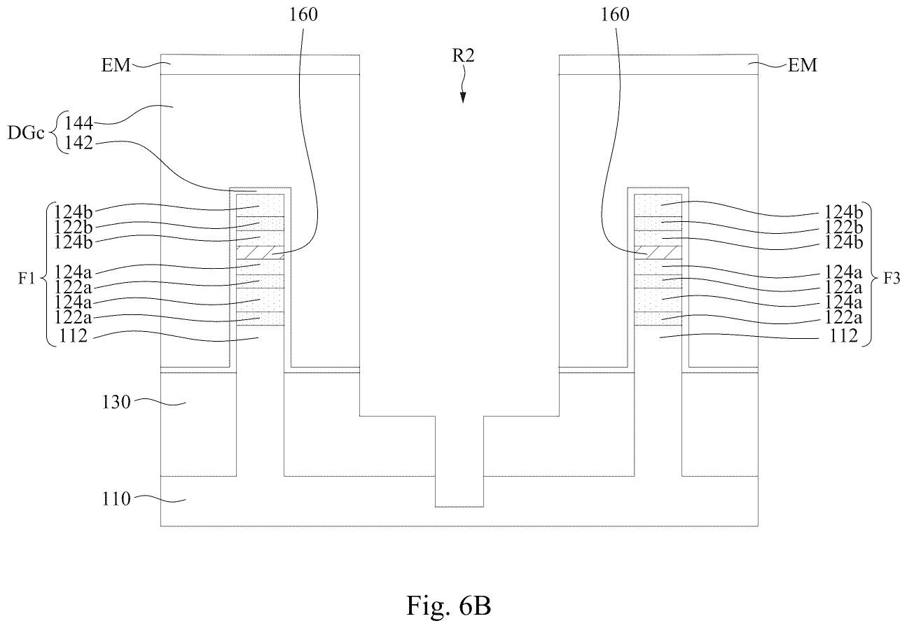

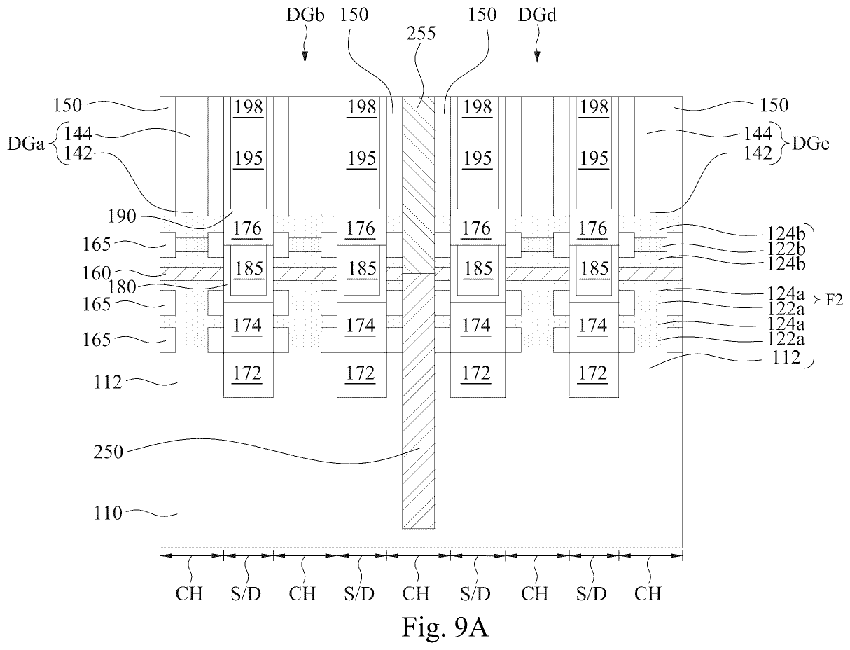

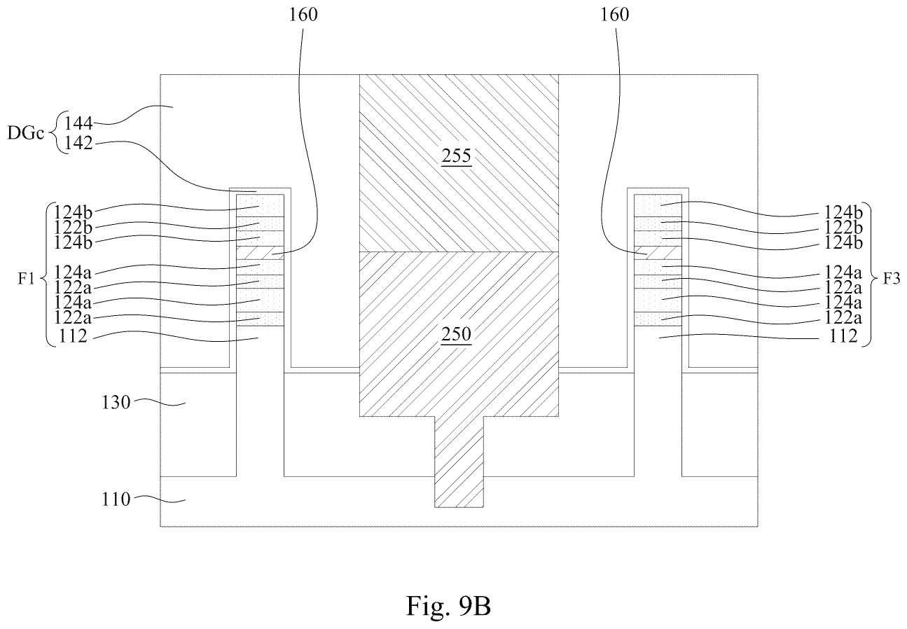

Reference is made to FIGS. 6A and 6B. A Cut-Poly on OD Edge (CPODE) process is performed. Specifically, a portion of the dummy gate structure DGc (see FIGS. 5A and 5B) is replaced with a bottom dielectric structure 250 and a top dielectric structure 255 (see FIGS. 9A and 9B). Specifically, an etching mask EM is formed to cover the dummy gate structures DGa, DGb, DGd, and DGe and portions of the dummy gate structure DGc. As shown in FIG. 6B, the etching mask EM covers portions of the dummy gate structure DGc over the fin structures F1 and F3 but exposes a portion of the dummy gate structure DGc over the fin structure F2 (see FIG. 5B).

An etching process is then performed by using the etching mask EM to etch the portion of the dummy gate structure DGc. In the etching process, the dummy gate structure DGc is first etched anisotropically, until the underlying fin structure F2 is exposed. The fin structure F2 and the middle dielectric isolator 160 are then etched, and the etching continues down into the underlying base portion 112 of the fin structure F2. Therefore, a recess R2 is formed in the dummy gate structure DGc.

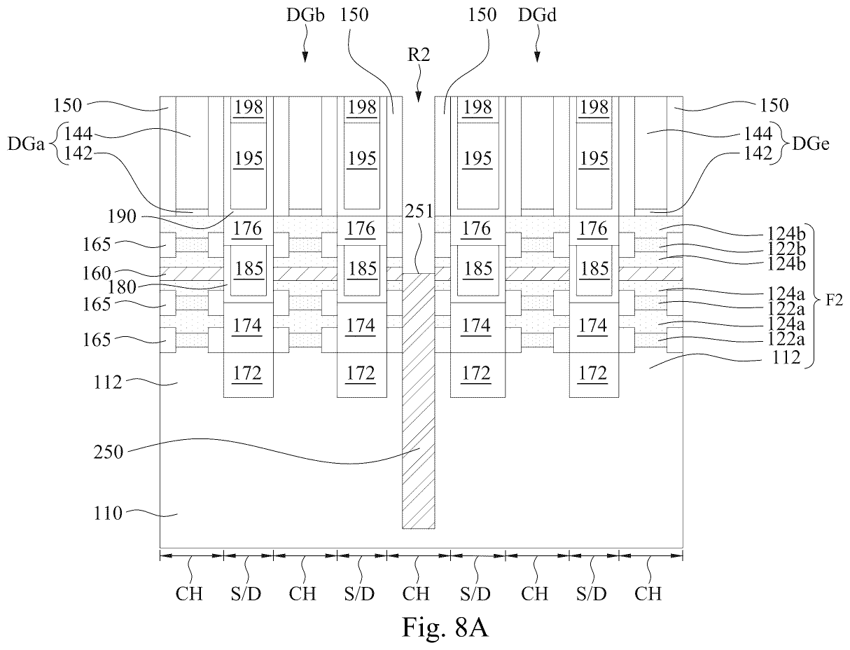

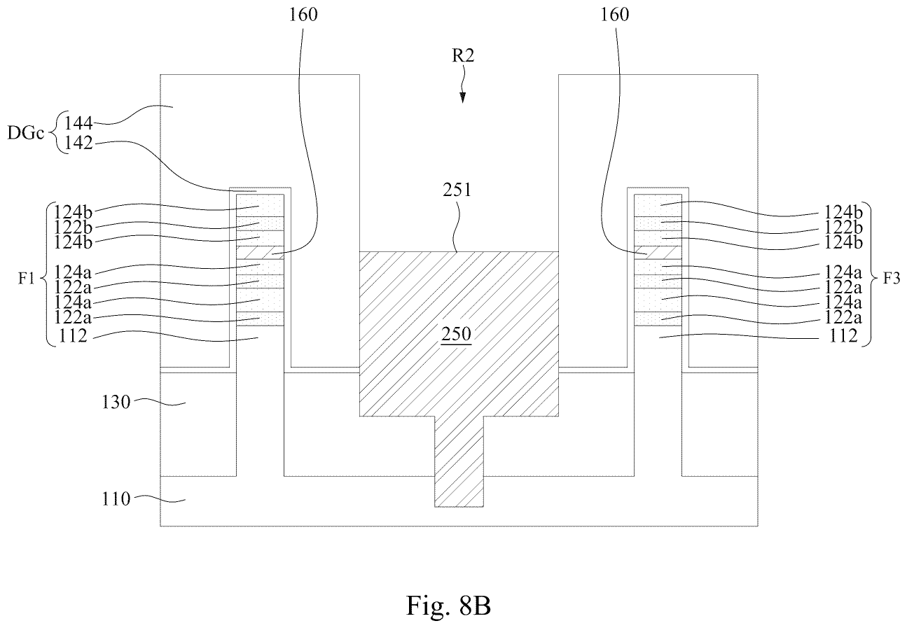

Since this etching process removes portions of the epitaxial layers 124a and 124b of the fin structure F2, the remaining epitaxial layers 124a and 124b neighboring the recess R2 (e.g., the epitaxial layers 124a and 124b under the dummy gate structures DGb and DGd) suffer uneven stresses from opposite sides thereof. Therefore, the following formed bottom dielectric structure 250 (see FIGS. 8A and 8B) is configured to restore the channel stress of the remaining epitaxial layers 124a, and the following formed top dielectric structure 255 (see FIGS. 9A and 9B) is configured to restore the channel stress of the remaining epitaxial layers 124b.

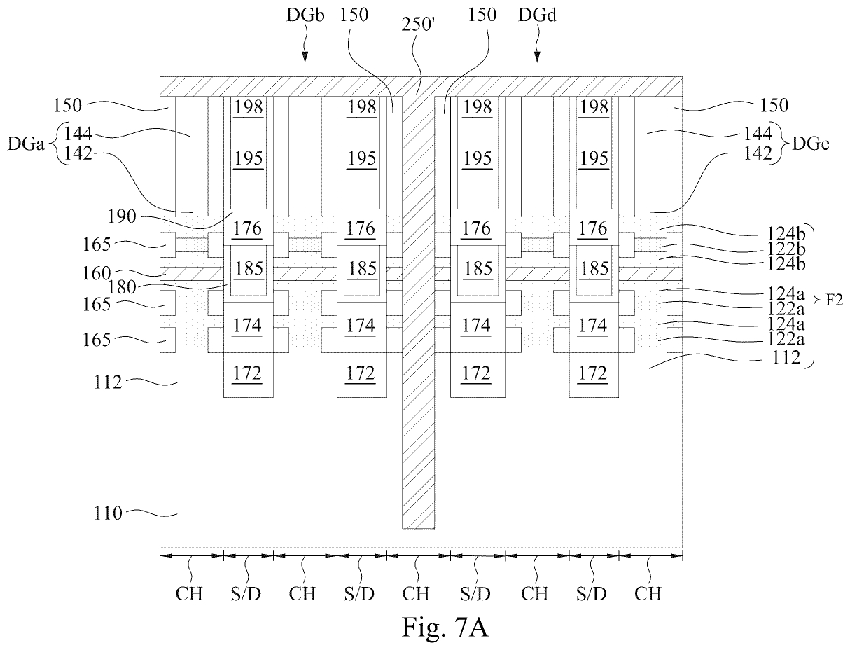

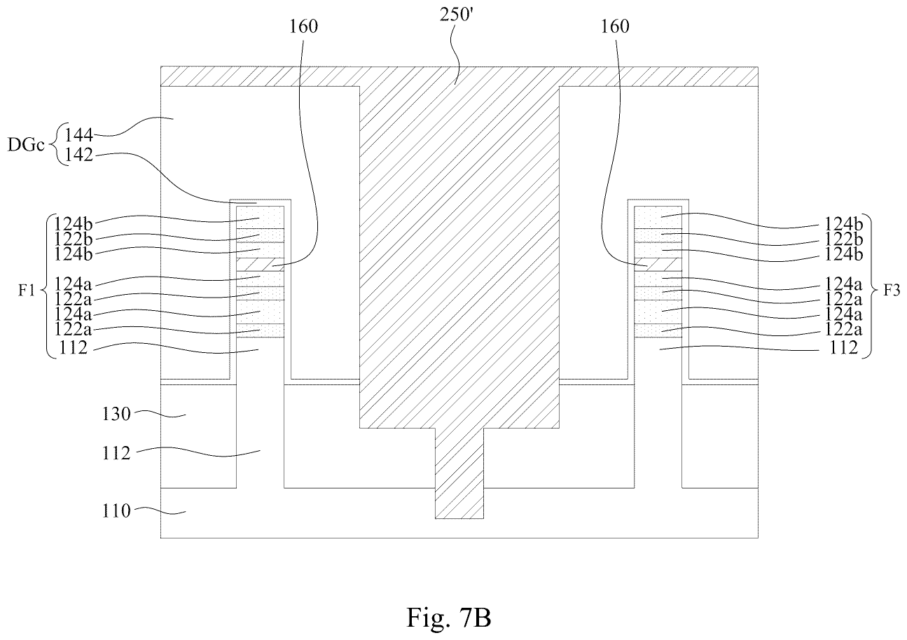

Reference is made to FIGS. 7A and 7B. The etching mask EM in FIGS. 6A and 6B is removed. A first dielectric material then fills the recess R2 to form a dielectric structure 250′. The first dielectric material may be deposited by CVD, ALD, spin-on coating, or other suitable techniques. The first dielectric material may include silicon nitride, silicon oxynitride, SiCN, SiCON, combinations thereof, and/or other suitable dielectric material layer.

By adjusting formation process conditions, the material, and the treatment conditions of the dielectric structure 250′, the dielectric structure 250′ may apply a compressive stress, a tensile stress, or a neutral stress. Throughout the description, when a compressive stress or a tensile stress applied on the epitaxial layers 124a and 124b is referred to, the compressive stress or the tensile stress has a magnitude higher than about 1 Pa. Furthermore, when a neutral stress is referred to, the neutral stress refers to no stress or stresses with stress magnitude smaller than about 1 Pa. In some exemplary embodiments, to make the dielectric structure 250′ to apply a compressive stress to the epitaxial layers 124a, the dielectric structure 250′ includes tensile silicon nitride. Specifically, the first dielectric material is formed by using the CVD process with H₂ plasma and N₂ plasma. In some embodiments, the H₂ plasma is applied with a first flow rate, and the N₂ plasma is applied with a second flow rate. With adjusting the ratio of the first flow rate and the second flow rate, the amount of N—H bonds in the dielectric structure 250′ is raised, and the dielectric structure 250′ itself becomes more tensile.

In some other embodiments, the first dielectric material is formed by using the CVD process with low frequency radio frequency (RF) signal and with a gas mixture including N₂ and Ar gases. In some embodiments, the N₂ gas is applied with a third flow rate, and the Ar gas is applied with a fourth flow rate. With adjusting the ratio of the third flow rate and the fourth flow rate, the amount of N—H bonds in the dielectric structure 250′ is raised, and the dielectric structure 250′ itself becomes more tensile. In some embodiments, the dielectric structure 250′ (and thus the bottom dielectric structure 250) has the tensile stress with a magnitude in a range of about 0 MPa to about 4.5 MPa.

Reference is made to FIGS. 8A and 8B. A planarization process includes a chemical mechanical planarization (CMP) process is performed to remove portions of the dielectric structure 250′ over the recess R2 until top surfaces of the dummy gate structures DGa-DGe and top surfaces of the dielectric caps 198 are exposed. Subsequently, an etching back process is performed to the dielectric structure 250′ to lower the top surface of the dielectric structure 250′. Therefore, a bottom dielectric structure 250 is formed in the recess R2. In some embodiments, the top surface 251 of the bottom dielectric structure 250 may be level with the bottom surface or the top surface of the middle dielectric isolators 160, or may be at an intermediate level between the top surface and the bottom surface of the middle dielectric isolators 160 as shown in FIGS. 8A and 8B. As mentioned above, the bottom dielectric structure 250 has the tensile stress, such that the epitaxial layers 124a become compressive. That is, the bottom dielectric structure 250 restores the compressive stress of the epitaxial layers 124a.

Reference is made to FIGS. 9A and 9B. A second dielectric material then fills the recess R2, and a planarization process such as a CMP process is performed to level the top surface of second dielectric material with the top surfaces of the top surfaces of the dummy gate structures DGa-DGe and top surfaces of the dielectric caps 198 to form a top dielectric structure 255. The second dielectric material may be deposited by CVD, ALD, spin-on coating, or other suitable techniques. The second dielectric material may include silicon nitride, silicon oxynitride, SiCN, SiCON, combinations thereof, and/or other suitable dielectric material layer.

In some exemplary embodiments, to make the top dielectric structure 255 to apply a tensile stress to the epitaxial layers 124b, the top dielectric structure 255 includes compressive silicon nitride. Specifically, in some embodiments, the second dielectric material is formed by using the CVD process with H₂ plasma and N₂ plasma. In some embodiments, the H₂ plasma is applied with a fifth flow rate, and the N₂ plasma is applied with a sixth flow rate. With adjusting the ratio of the fifth flow rate and the sixth flow rate, the amount of N—H bonds in the top dielectric structure 255 is lowered, and the top dielectric structure 255 itself becomes more compressive. For example, the fifth flow rate of the H₂ plasma is higher than the first flow rate of the H₂ plasma (mentioned above). Therefore, the top dielectric structure 255 is more compressive than the bottom dielectric structure 250.

In some other embodiments, the second dielectric material is formed by using the CVD process with low frequency radio frequency (RF) signal and with a gas mixture containing N₂ and Ar gases. In some embodiments, the N₂ gas is applied with a seventh flow rate, and the Ar gas is applied with an eighth flow rate. With adjusting the ratio of the seventh flow rate and the eighth flow rate, the amount of N—H bonds in the top dielectric structure 255 is lowered, and the top dielectric structure 255 itself becomes more compressive. For example, the eighth flow rate of the Ar gas is higher than the fourth flow rate of the Ar gas (mentioned above). Therefore, the top dielectric structure 255 is more compressive than the bottom dielectric structure 250. In some embodiments, the top dielectric structure 255 has the compressive stress with a magnitude in a range of about 0 MPa to about 5.5 MPa. With the compressive top dielectric structure 255, the epitaxial layers 124a become tensile. That is, the top dielectric structure 255 restores the tensile stress of the epitaxial layers 124a.

Reference is made to FIGS. 10A-10C. Thereafter, a gate replacement process is performed. Specifically, the dummy gate electrode layer 144 and the dummy gate dielectric layer 142 are removed, and then the epitaxial layers (i.e., sacrificial layers) 122a-122b are removed. In some embodiments, the dummy gate electrode layers 144 and the dummy gate dielectric layer 142 are removed by using a selective etching process (e.g., selective dry etching, selective wet etching, or combinations thereof) that etches the materials in dummy gate electrode layers 144 and the dummy gate dielectric layer 142 at a faster etch rate than it etches other materials (e.g., the gate spacers 150 and/or the dielectric caps 198), thus resulting in gate trenches between the gate spacers 150, with the epitaxial layers 122a and 122b exposed in the gate trenches. Subsequently, the epitaxial layers 122a and 122b in the gate trenches are removed by using another selective etching process that etches the epitaxial layers 122a and 122b at a faster etch rate than it etches the epitaxial layers 124a and 124b, thus forming openings between neighboring epitaxial layers 124a and 124b. In this way, the epitaxial layers 124a and 124b become nanosheets suspended over the substrate 110. This operation is also called a channel release process. In some embodiments, the epitaxial layers 124a and 124b can be interchangeably referred to as nanostructure (nanowires, nanoslabs and nanorings, nanosheet, etc., depending on their geometry). For example, in some other embodiments the epitaxial layers 124a and 124b may be trimmed to have a substantial rounded shape (i.e., cylindrical) due to the selective etching process for completely removing the epitaxial layers 124a and 124b. In that case, the resultant epitaxial layers 124a and 124b can be called nanowires.

In some embodiments, the epitaxial layers 122a and 122b are removed by using a selective dry etching process by using, for example, CF₄ as etching gases. In some embodiments, the epitaxial layers 122a and 122b are SiGe and the epitaxial layers 124a and 124b are silicon allowing for the selective removal of the epitaxial layers 122a and 122b.

Interfacial layers 212 are then formed around the epitaxial layers 124a and 124b. In some embodiments, the interfacial layer 212 may include a dielectric material such as silicon oxide (SiO₂), HfSiO, or silicon oxynitride (SiON). The interfacial layers 212 may be formed by chemical oxidation, thermal oxidation, atomic layer deposition (ALD), chemical vapor deposition (CVD), and/or other suitable method. In some embodiments, when the interfacial layers 212 are formed by oxidation, the interfacial layers 212 are grown on the surfaces of semiconductor materials, such as the epitaxial layers 124a and 124b.

Thereafter, high-k gate dielectric layers 214 are formed to cover the interfacial layers 212. High-k gate dielectrics include dielectric materials having a high dielectric constant, for example, greater than that of thermal silicon oxide (˜3.9). The high-k gate dielectric layer 214 of the gate dielectric layer may include hafnium oxide (HfO₂). Alternatively, the high-k gate dielectric layer 214 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO2), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. The high-k gate dielectric layers 214 may be formed by atomic layer deposition (ALD), chemical vapor deposition (CVD), and/or other suitable method.

Next, a work function metal layer 216 is deposited in the gate trenches and fills the gate trenches. The work function metal layer 216 may include work function metals to provide a suitable work function for (metal) gate structures MGB. For a p-type FET, the work function metal layer 216 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. The work function metal layer 216 may be formed by atomic layer deposition (ALD), chemical vapor deposition (CVD), and/or other suitable method. Subsequently, one or more CMP processes are performed to remove excessive gate materials.

After the formation of the work function metal layer 216, the work function metal layer 216 is etched back by using an etching process, and the top portions of the high-k gate dielectric layers 214 are exposed. Subsequently, another work function metal layer 218 is deposited in the gate trenches and over the work function metal layer 216 and fill the gate trenches. For an n-type FET, the work function metal layer 218 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials.

Therefore, the interfacial layers 212, the high-k gate dielectric layers 214, and the work function metal layer 216 form (metal) gate structures MGB, and the interfacial layers 212, the high-k gate dielectric layers 214, and the work function metal layer 218 form (metal) gate structures MGT over the gate structures MGB.

Reference is made to FIGS. 11A-11C. After the formation of the gate structures MGB and MGT as shown in FIGS. 10A-10C, an etching back process is optionally performed to etch back the gate structures MGT, resulting in recesses over the etched-back gate structures MGT. In some embodiments, because the materials of the gate structures MGT have a different etch selectivity than the gate spacers 150, a selective etching process may be performed to etch back the gate structures MGT to lower the gate structures MGT. As a result, the top surface of the gate structures MGT may be at a lower level than the top surfaces of the gate spacers 150.

Subsequently, a dielectric cap layer is deposited over the substrate 110 until the recesses are overfilled. The dielectric cap layer includes SiNₓ, AlₓO_{y}, AlON, SiOₓC_{y}, SiCₓN_{y}, boron nitride (BN), boron carbonitride (BNC), combinations thereof or the like, and is formed by a suitable deposition technique such as CVD, plasma-enhanced CVD (PECVD), ALD, remote plasma ALD (RPALD), plasma-enhanced ALD (PEALD), combinations thereof or the like. A CMP process is then performed to remove the cap layer outside the recess, leaving portions of the dielectric cap layer in the recess to serve as dielectric caps 220. The dielectric caps 220 are in direct contact with the gate structures MGT as shown in FIGS. 11A-11C.

Next, openings are formed in the second ILD layer 195. The opening exposes the second source/drain epitaxial structures 176. Source/drain contacts 230 are then respectively formed in the openings. In some embodiments, prior to the formation of the source/drain contacts 230, metal alloy layers are formed in the openings and on the exposed portions of the second source/drain epitaxial structures 176. Each of the source/drain contacts 230 is connected to the corresponding second source/drain epitaxial structure 176. Formation of the source/drain contacts 230 includes depositing one or more conductive (e.g., metal) materials overfilling the openings and then performing a CMP process to remove excessive metal materials outside the openings.

As such, the semiconductor device 100a is formed. As shown in FIGS. 11A-11C, the semiconductor device 100a includes bottom (nanostructure) transistors BT, top (nanostructure) transistors TT, a bottom dielectric structure 250, and a top dielectric structure 255. The top transistors TT are above the bottom transistors BT, respectively. The bottom dielectric structure 250 is between the bottom transistors BT, and the top dielectric structure 255 is between the top transistors TT and in contact with the bottom dielectric structure 250.

The top transistors TT and the bottom transistors BT are different types of GAA transistors. For example, the top transistors TT are n-type transistors, and the bottom transistors BT are p-type transistors. The bottom dielectric structure 250 itself has a tensile stress with a magnitude in a range of about 0 MPa to about 4.5 MPa, such that the bottom dielectric structure 250 restores the stress of the epitaxial layers 124a. That is, the epitaxial (channel) layers 124a have sufficient compressive stress. Likewise, the top dielectric structure 255 itself has a compressive stress with a magnitude in a range of about 0 MPa to about 5.5 MPa, such that the top dielectric structure 255 restores the stress of the epitaxial layers 124b. That is, the epitaxial (channel) layers 124b have sufficient tensile stress. The bottom dielectric structure 250 has a stress more tensile than a stress of the top dielectric structure 255, and the top dielectric structure 255 has the stress more compressive than the stress of the bottom dielectric structure 250. In some embodiments, the top dielectric structure 255 and the bottom dielectric structure 250 are both made of silicon nitride or substantially silicon nitride, and an amount of N—H bonds in the bottom dielectric structure 250 is higher than an amount of N—H bonds in the top dielectric structure 255.

In FIG. 11A, the bottom dielectric structure 250 has a bottom surface 252 lower than a bottom surface 175a of the first source/drain epitaxial structures 174. The interface 258 between the bottom dielectric structure 250 and the top dielectric structure 255 is higher than a top surface 175b of the first source/drain epitaxial structures 174 and lower than a bottom surface 177a of the second source/drain epitaxial structures 176. Furthermore, the interface 258 between the bottom dielectric structure 250 and the top dielectric structure 255 is higher than a position of the epitaxial layer (or channel layer) 124a connected to the first source/drain epitaxial structures 174 and lower than a position of the epitaxial layer (or channel layer) 124b connected to the second source/drain epitaxial structures 176. The top surface 256 of the top dielectric structure 255 is higher than the top surface of the bottom dielectric structure 250 (i.e., the interface 258).

The bottom dielectric structure 250 is in contact with the inner dielectric spacers 165 and the middle dielectric isolators 160, and the top dielectric structure 255 is in contact with the inner dielectric spacers 165, the middle dielectric isolators 160, and the gate spacers 150. The bottom dielectric structure 250 and the top dielectric structure 255 are substantially coterminous.

In FIG. 11B, the bottom dielectric structure 250 is in contact with the gate structures MGB, and the top dielectric structure 255 is in contact with the gate structures MGT. The bottom dielectric structure 250 is deeper than the gate structures MGB. As shown in FIG. 11B, a bottom portion of the bottom dielectric structure 250 has a width W1 smaller than a width W2 of a top portion of the bottom dielectric structure 250. Further, the width W2 of the top portion of the bottom dielectric structure 250 is substantially the same with a width W3 of the top dielectric structure 255. The semiconductor device 100a further includes isolation structures 130 between the substrate 110 and the gate structures MGB of the bottom transistors BT. The bottom surface 252 of the bottom dielectric structure 250 is lower than a bottom surface 131 of the isolation structures 130, and the top surface of the bottom dielectric structure 250 (i.e., the interface 258) (or the bottom surface of the top dielectric structure 255) is higher than a top surface 132 of the isolation structures 130. The interface 258 between the bottom dielectric structure 250 and the top dielectric structure 255 is substantially level with the interface 217 between the work function metal layers 216 and 218 of the gate structures MGB and MGT.

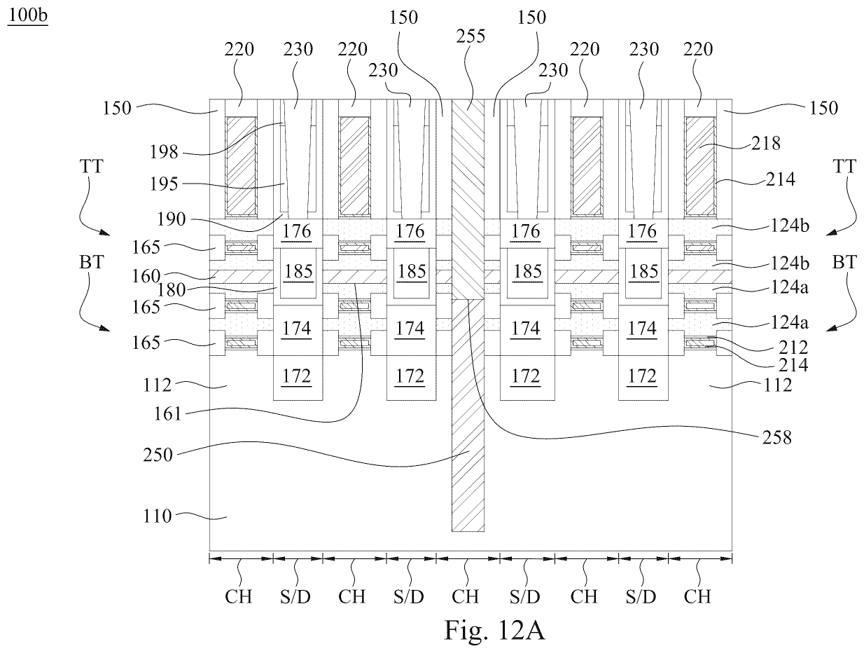

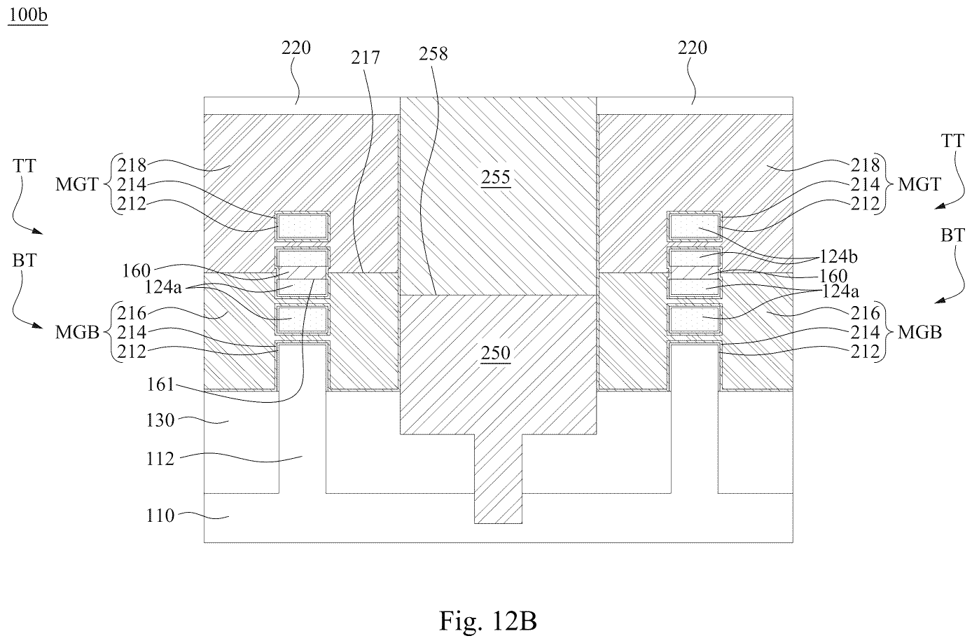

FIGS. 12A and 12B are cross-sectional view of integrated circuit structure (or a semiconductor device) 100b in accordance with some embodiments of the present disclosure. The difference between the semiconductor device 100b in FIGS. 12A and 12B and the semiconductor device 100 a in FIGS. 11A-11C pertains to the position of the interface 258 between the bottom dielectric structure 250 and the top dielectric structure 255. In FIGS. 12A and 12B, the interface 258 between the bottom dielectric structure 250 and the top dielectric structure 255 is at a level lower than a bottom surface 161 of the middle dielectric isolators 160 and higher than a position of the epitaxial layer 124a that connected to the first source/drain epitaxial structures 174. Further, as shown in FIG. 12B, the interface 258 between the bottom dielectric structure 250 and the top dielectric structure 255 is at a level lower than an interface 217 between the work function metal layers 216 and 218 of the gate structures MGB and MGT. Other relevant structural and manufacturing details of the semiconductor device 100b are substantially the same or similar to the semiconductor device 100a of FIGS. 11A-11C, and, therefore, a description in this regard will not be repeated hereinafter.

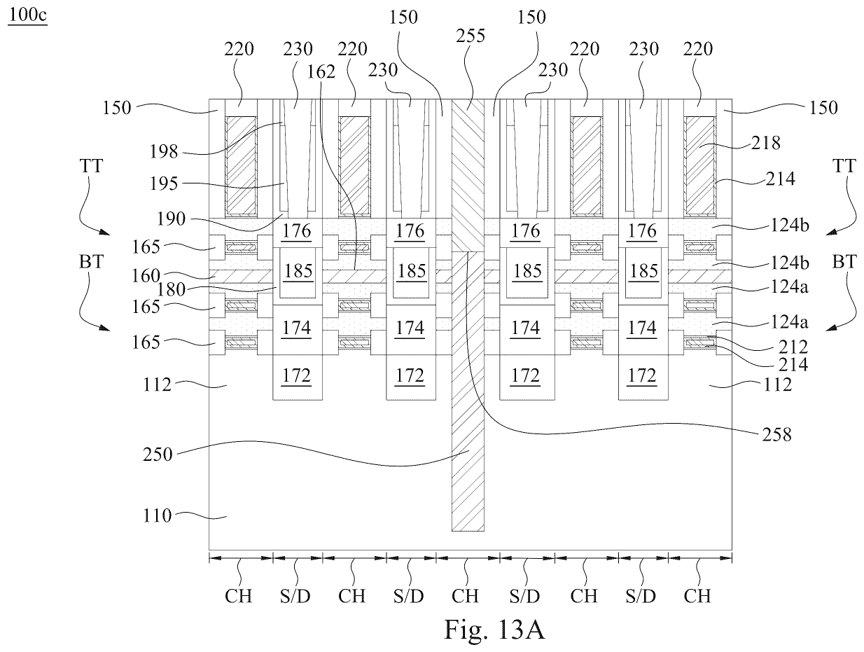

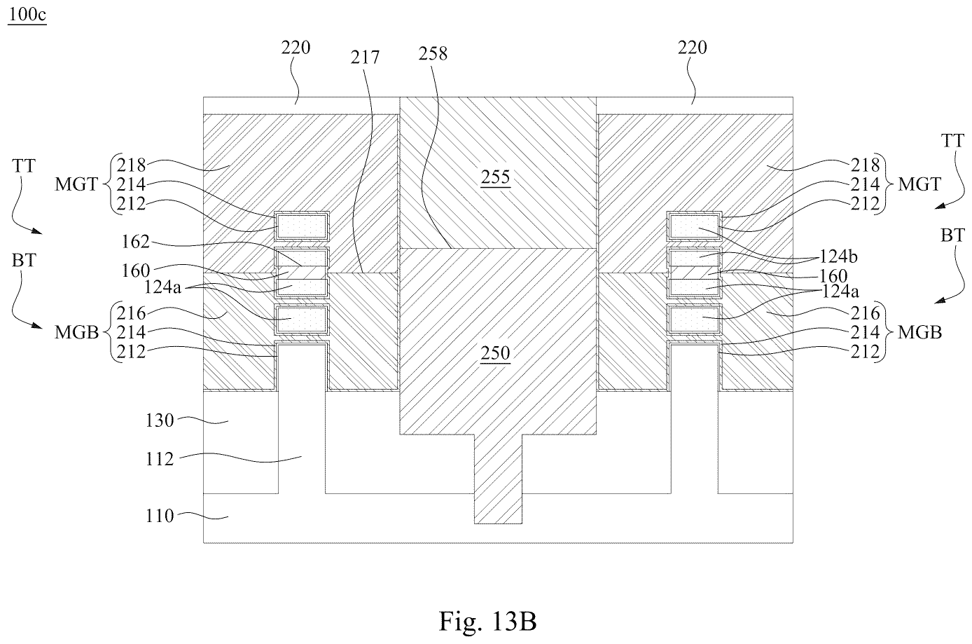

FIGS. 13A and 13B are cross-sectional view of integrated circuit structure (or a semiconductor device) 100c in accordance with some embodiments of the present disclosure. The difference between the semiconductor device 100c in FIGS. 13A and 13B and the semiconductor device 100 a in FIGS. 11A-11C pertains to the position of the interface 258 between the bottom dielectric structure 250 and the top dielectric structure 255. In FIGS. 13A and 13B, the interface 258 between the bottom dielectric structure 250 and the top dielectric structure 255 is at a level higher than a top surface 162 of the middle dielectric isolators 160 and lower than a position of the epitaxial layer 124b that connected to the second source/drain epitaxial structures 176. Further, as shown in FIG. 13B, the interface 258 between the bottom dielectric structure 250 and the top dielectric structure 255 is at a level higher than the interface 217 between the work function metal layers 216 and 218 of the gate structures MGB and MGT. Other relevant structural and manufacturing details of the semiconductor device 100c are substantially the same or similar to the semiconductor device 100a of FIGS. 11A-11C, and, therefore, a description in this regard will not be repeated hereinafter.

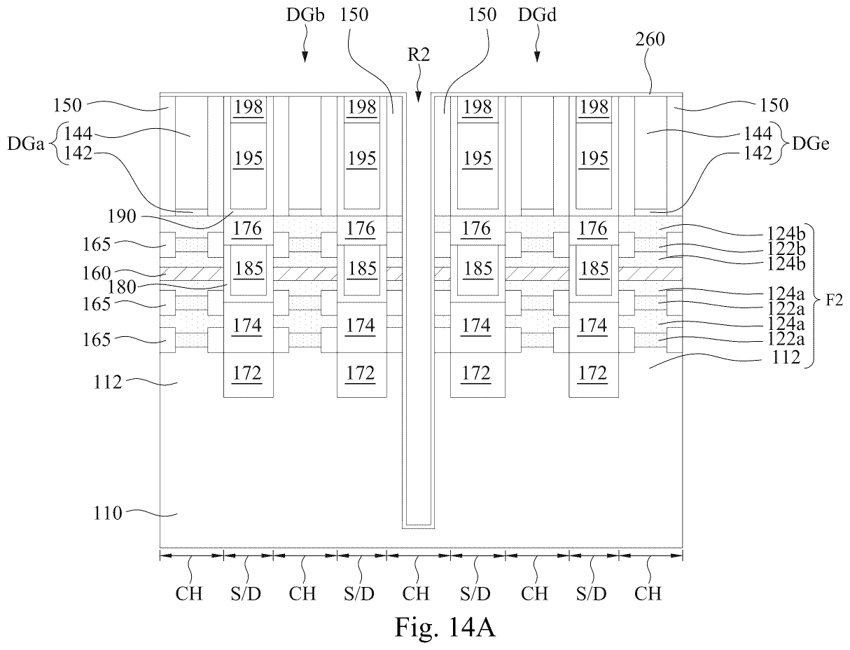

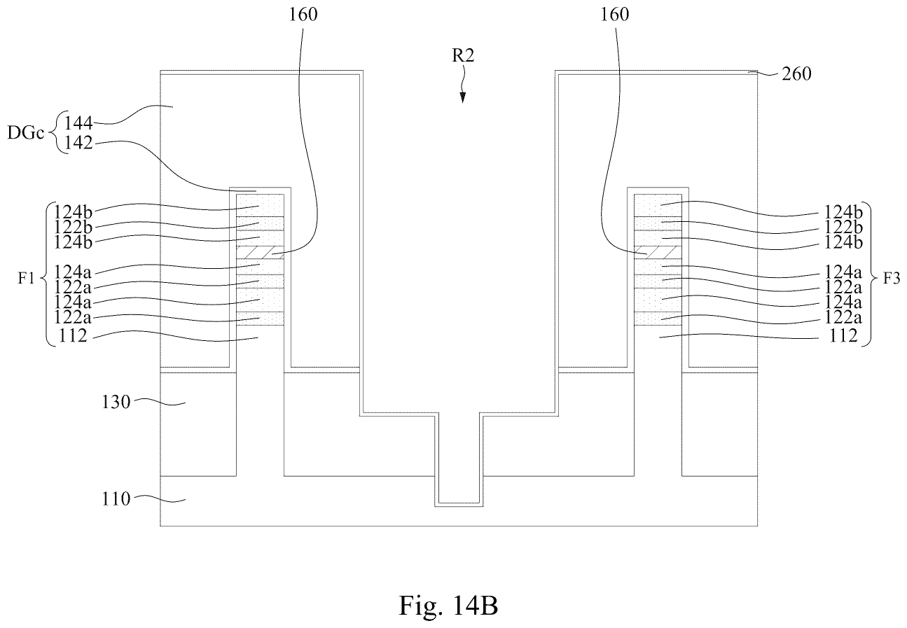

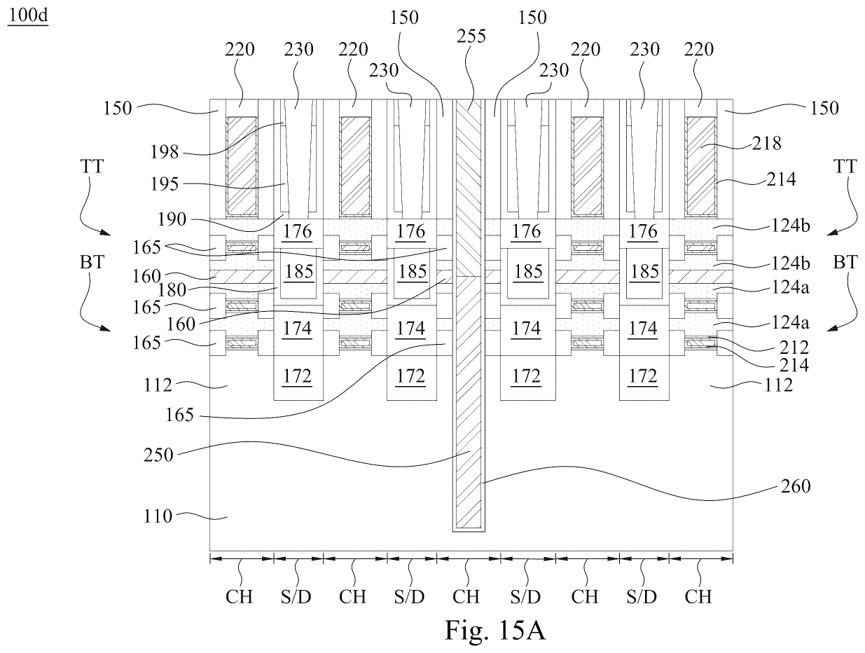

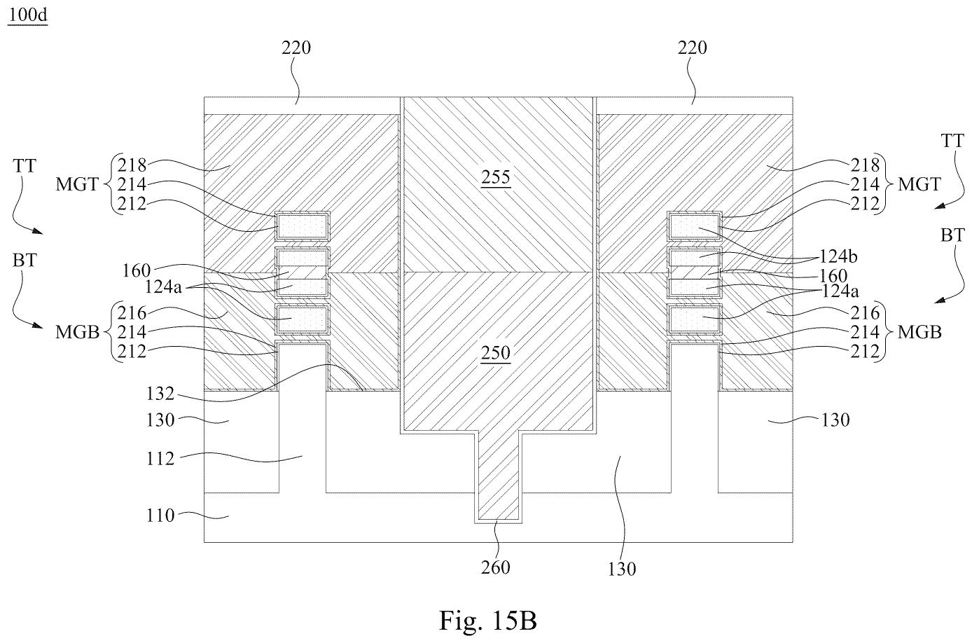

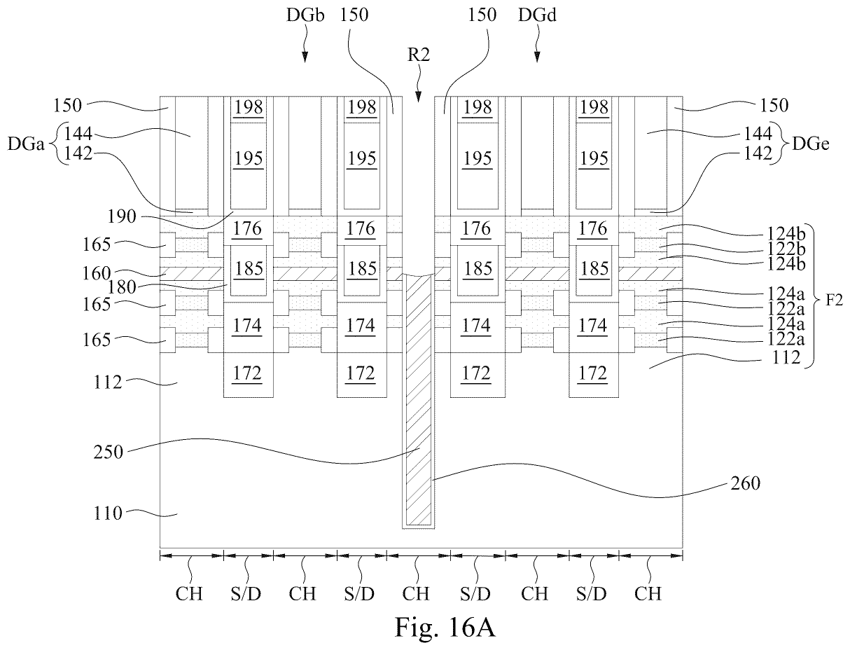

FIGS. 14A-15B illustrate exemplary cross-sectional views of various stages for manufacturing an integrated circuit structure (or a semiconductor device) 100d according to some other embodiments of the present disclosure. It is understood that additional operations can be provided before, during, and after processes shown by FIGS. 14A-15B, and some of the operations described below can be replaced or eliminated, for additional embodiments of the method. The order of the operations/processes may be interchangeable. The same or similar configurations, materials, processes and/or operation as described with FIGS. 2-11C may be employed in the following embodiments, and the detailed explanation may be omitted.

Reference is made to FIGS. 14A and 14B. After the process shown in FIGS. 6A-6B is performed, the etching mask EM in FIGS. 6A and 6B is removed. A dielectric liner 260 is then formed to line sidewalls and bottom of the recess R2. In some embodiments, the dielectric liner 260 may be an oxygen-free liner. In some embodiments, the dielectric liner 260 may include SiOCN formed by a deposition process.

Reference is made to FIGS. 15A and 15B. The structure in FIGS. 14A-14B then undergoes the processes shown in FIGS. 7A-11B. As such, the semiconductor device 100d is provided. In FIGS. 15A and 15B, the dielectric liner 260 is in contact with and laterally surrounds the bottom dielectric structure 250 and the top dielectric structure 255. Further, the dielectric liner 260 is in contact with the gate structures MGT and MGB and the isolation structure 130. Other relevant structural and manufacturing details of the semiconductor device 100d are substantially the same or similar to the semiconductor device 100a of FIGS. 11A-11C, and, therefore, a description in this regard will not be repeated hereinafter.

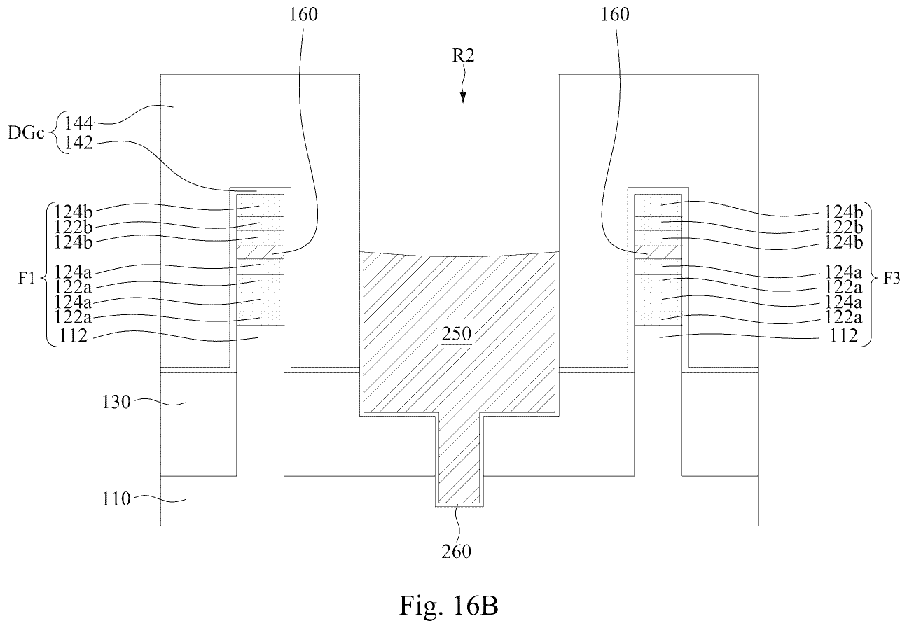

FIGS. 16A-18B illustrate exemplary cross-sectional views of various stages for manufacturing an integrated circuit structure (or a semiconductor device) 100e according to some other embodiments of the present disclosure. It is understood that additional operations can be provided before, during, and after processes shown by FIGS. 16A-18B, and some of the operations described below can be replaced or eliminated, for additional embodiments of the method. The order of the operations/processes may be interchangeable. The same or similar configurations, materials, processes and/or operation as described with FIGS. 2-11C may be employed in the following embodiments, and the detailed explanation may be omitted.

Reference is made to FIGS. 16A and 16B. After the process shown in FIGS. 6A-6B is performed, the etching mask EM in FIGS. 6A and 6B is removed. A dielectric liner 260 is then formed to line sidewalls and bottom of the recess R2. In some embodiments, the dielectric liner 260 may be an oxygen-free liner. In some embodiments, the dielectric liner 260 may include SiOCN formed by a deposition process.

The dielectric deposition and the etching back processes shown in FIGS. 7A-8B are then performed. During the etching back process as described in FIGS. 8A and 8B, the dielectric liner 260 is also etched back, such that a top surface of the dielectric liner 260 is substantially coplanar with the top surface of the bottom dielectric structure 250. In some embodiments, the top surface of the bottom dielectric structure 250 may be curved (e.g., concave) due to the etching process.

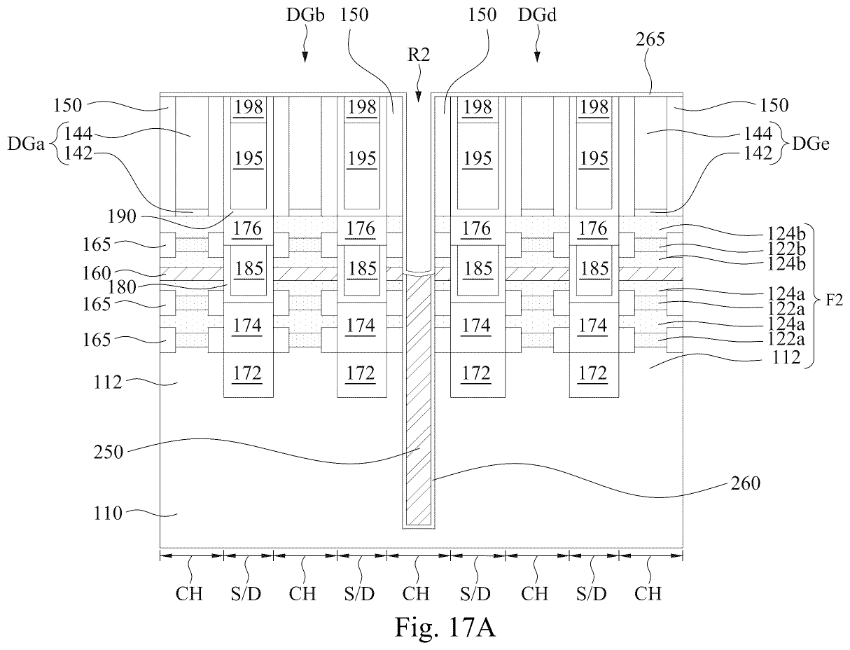

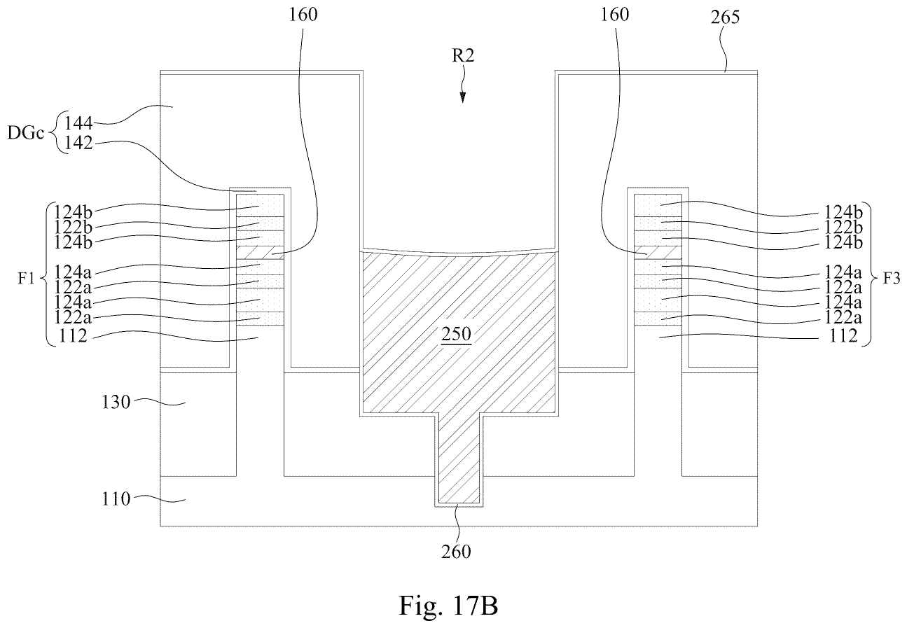

Reference is made to FIGS. 17A and 17B. Another dielectric liner 265 is then formed to line sidewalls of the recess R2 and the top surface of the bottom dielectric structure 250. In some embodiments, the dielectric liner 265 may be an oxygen-free liner. In some embodiments, the dielectric liner 265 may include SiOCN formed by a deposition process.

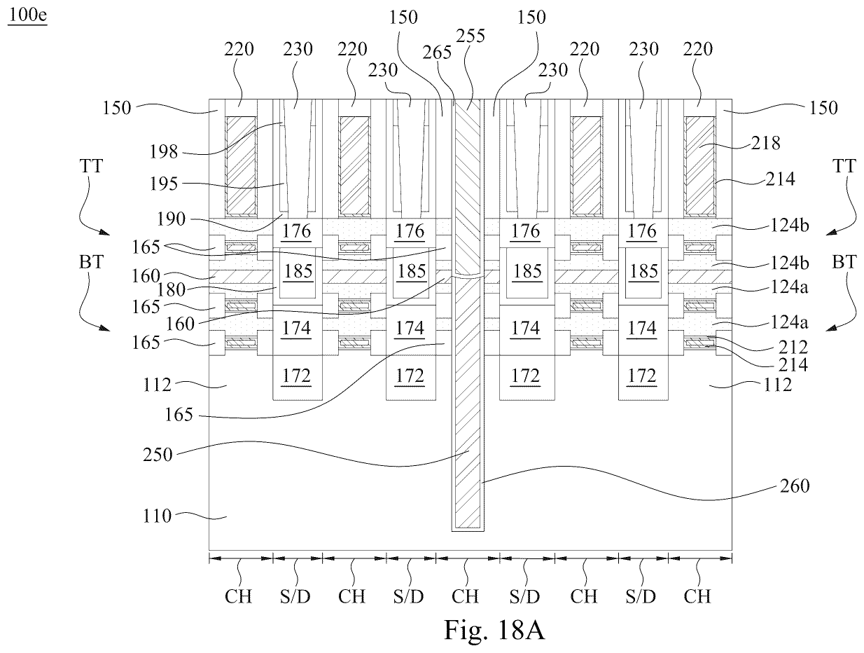

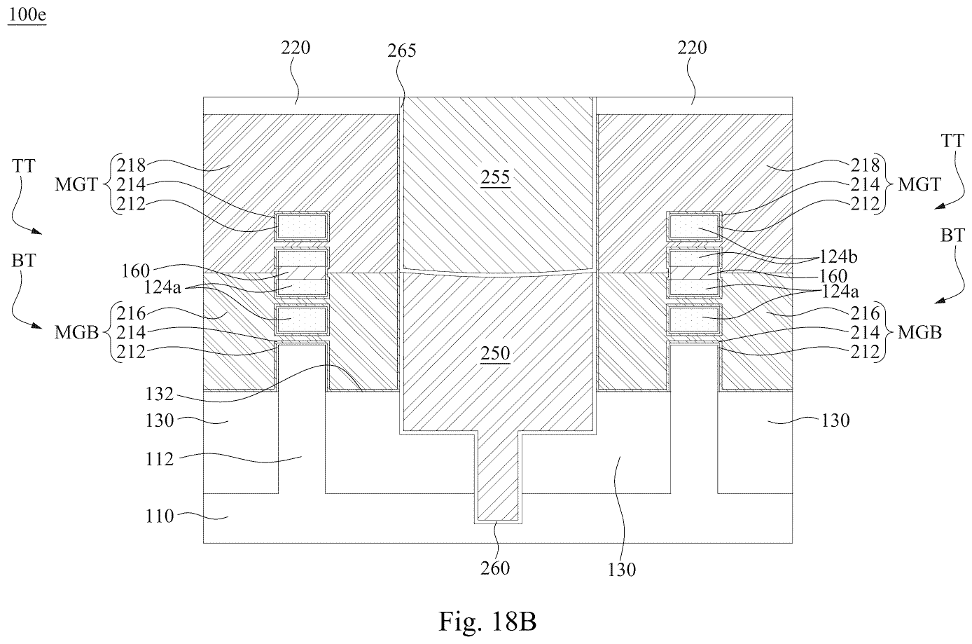

Reference is made to FIGS. 18A and 18B. The structure in FIGS. 17A-17B then undergoes the processes shown in FIGS. 9A-11B. As such, the semiconductor device 100e is provided. In FIGS. 18A and 18B, the dielectric liner 260 is in contact with and laterally surrounds the bottom dielectric structure 250, and the dielectric liner 265 is in contact with and laterally surrounds the top dielectric structure 255. Further, the dielectric liner 260 is in contact with the gate structure MGB and the isolation structure 130, and the dielectric liner 265 is in contact with the gate structure MGT. Other relevant structural and manufacturing details of the semiconductor device 100e are substantially the same or similar to the semiconductor device 100a of FIGS. 11A-11C, and, therefore, a description in this regard will not be repeated hereinafter.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the bottom dielectric structure itself has a tensile stress to restore the stress of the channel layer of the bottom transistor, while the top structure itself has a compressive stress to restore the stress of the channel layer of the top transistor. Further, the stresses of the bottom dielectric structure and the top dielectric structure can be tuned by applying suitable frequency of plasma and/or suitable material of plasma, simplifying the manufacturing process of the bottom and top dielectric structures.

According to some embodiments, a device includes a first bottom transistor, a second bottom transistor, a first top transistor, a second top transistor, a bottom dielectric structure, and a top dielectric structure. The first top transistor is over the first bottom transistor. The second top transistor is over the second bottom transistor. The bottom dielectric structure is between the first bottom transistor and the second bottom transistor. The top dielectric structure is between the first top transistor and the second top transistor and in contact with the bottom dielectric structure. The bottom dielectric structure and the top dielectric structure have different stresses.

According to some embodiments, a device includes a bottom transistor, a top transistor, a bottom dielectric structure, and a top dielectric structure. The bottom transistor includes a first channel layer, a first gate structure, and first source/drain epitaxial structures. The first gate structure wraps around the first channel layer. The first source/drain epitaxial structures are on opposite sides of the first gate structure and are connected to the first channel layer. The top transistor is over the bottom transistor to form a complementary field effect transistor and includes a second channel layer, a second gate structure, and second source/drain epitaxial structures. The second channel layer is over the bottom transistor. The second gate structure wraps around the second channel layer. The second source/drain epitaxial structures are on opposite sides of the second gate structure and are connected to the second channel layer. The bottom dielectric structure is in contact with the first gate structure. The top dielectric structure is in contact with the second gate structure and has a stress more compressive than a stress of the bottom dielectric structure.

According to some embodiments, a method includes forming a first fin structure and a second fin structure over a substrate. The first fin structure includes a first channel layer, a sacrificial layer, and a second channel layer from bottom to top. A dummy gate structure is formed over the substrate and across the first fin structure and the second fin structure. First recesses are formed in the first fin structure by using the dummy gate structure as an etch mask. First source/drain epitaxial structures are grown in the first recesses of the first fin structure to be connected to the first channel layer. Second source/drain epitaxial structures are grown in the recesses of the first fin structure to be connected to the second channel layer. A portion of the dummy gate structure and a portion of the second fin structure are removed to form a second recess in the dummy gate structure. A bottom dielectric structure is formed in the second recess. A top dielectric structure is deposited in the second recess and over the bottom dielectric structure. The top dielectric structure and the bottom dielectric structure have different stresses. The dummy gate structure and the sacrificial layer are replaced with a bottom gate structure and a top gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a first bottom transistor and a second bottom transistor;
a first top transistor over the first bottom transistor;
a second top transistor over the second bottom transistor;
a bottom dielectric structure between the first bottom transistor and the second bottom transistor; and
a top dielectric structure between the first top transistor and the second top transistor and in contact with the bottom dielectric structure, wherein the bottom dielectric structure and the top dielectric structure have different stresses.

2. The device of claim 1, wherein the stress of the bottom dielectric structure is tensile, and the stress of the top dielectric structure is compressive.

3. The device of claim 1, wherein an interface between the bottom dielectric structure and the top dielectric structure is higher than a position of a channel layer of the first bottom transistor.

4. The device of claim 1, wherein the bottom dielectric structure and the top dielectric structure are substantially coterminous.

5. The device of claim 1, further comprising a middle dielectric isolator between the first bottom transistor and the first top transistor.

6. The device of claim 5, wherein the top dielectric structure is in contact with the middle dielectric isolator.

7. The device of claim 5, wherein the bottom dielectric structure is in contact with the middle dielectric isolator.

8. The device of claim 1, wherein the bottom dielectric structure is deeper than a gate structure of the first bottom transistor.

9. The device of claim 1, wherein a top surface of the top dielectric structure is higher than a top surface of the bottom dielectric structure.

10. The device of claim 1, wherein the top dielectric structure and the bottom dielectric structure are both made of silicon nitride.

11. A device comprising:
a bottom transistor comprising:
a first channel layer;
a first gate structure wrapping around the first channel layer; and
first source/drain epitaxial structures on opposite sides of the first gate structure and connected to the first channel layer;
a top transistor over the bottom transistor to form a complementary field effect transistor, the top transistor comprising:
a second channel layer over the bottom transistor;
a second gate structure wrapping around the second channel layer; and
second source/drain epitaxial structures on opposite sides of the second gate structure and connected to the second channel layer;
a bottom dielectric structure in contact with the first gate structure; and
a top dielectric structure in contact with the second gate structure and having a stress more compressive than a stress of the bottom dielectric structure.

12. The device of claim 11, wherein an interface between the bottom dielectric structure and the top dielectric structure is substantially level with an interface between the first gate structure and the second gate structure.

13. The device of claim 11, further comprising an isolation structure under the first gate structure of the bottom transistor, wherein a bottom surface of the bottom dielectric structure is lower than a bottom surface of the isolation structure.

14. The device of claim 11, further comprising an isolation structure under the first gate structure of the bottom transistor, wherein a top surface of the bottom dielectric structure is higher than a top surface of the isolation structure.

15. The device of claim 11, further comprising an isolation structure under the first gate structure of the bottom transistor, wherein a bottom surface of the top dielectric structure is higher than a top surface of the isolation structure.

16. The device of claim 11, wherein a top surface of the bottom dielectric structure is lower than a top surface of the top dielectric structure.

17. The device of claim 11, wherein the bottom dielectric structure and the top dielectric structure are both made of silicon nitride.

18. A method comprising:
forming a first fin structure and a second fin structure over a substrate, the first fin structure comprising a first channel layer, a sacrificial layer, and a second channel layer from bottom to top;
forming a dummy gate structure over the substrate and across the first fin structure and the second fin structure;
forming first recesses in the first fin structure by using the dummy gate structure as an etch mask;
growing first source/drain epitaxial structures in the first recesses of the first fin structure to be connected to the first channel layer;
growing second source/drain epitaxial structures in the first recesses of the first fin structure to be connected to the second channel layer;
removing a portion of the dummy gate structure and a portion of the second fin structure to form a second recess in the dummy gate structure;
forming a bottom dielectric structure in the second recess;
depositing a top dielectric structure in the second recess and over the bottom dielectric structure, wherein the top dielectric structure and the bottom dielectric structure have different stresses; and
replacing the dummy gate structure and the sacrificial layer with a bottom gate structure and a top gate structure.

19. The method of claim 18, wherein the bottom dielectric structure has a tensile stress, and the top dielectric structure has a compressive stress.

20. The method of claim 18, wherein an amount of N—H bonds in the bottom dielectric structure is higher than an amount of N—H bonds in the top dielectric structure.
